(19) United States
(12) Patent Application Publication
(10) Pub. No.: US 2019/0081223 A1
(43) Pub. Date: Mar. 14, 2019

(54) SELF-GENERATION SENSOR DEVICE AND SELF-GENERATION SENSOR SYSTEM USING THE SAME

(71) Applicants: KOREA ADVANCED INSTITUTE OF SCIENCE AND TECHNOLOGY, Daejeon (KR); TEGWAY CO., LTD., Daejeon (KR)

(72) Inventors: Byung Jin CHO, Daejeon (KR); Yongjun KIM, Daejeon (KR); Choong Sun KIM, Daejeon (KR); Kyoung Soo YI, Daejeon (KR)

(73) Assignees: KOREA ADVANCED INSTITUTE OF SCIENCE AND TECHNOLOGY, Daejeon (KR); TEGWAY CO., LTD., Daejeon (KR)

(21) Appl. No.: 16/083,460

(22) PCT Filed: Mar. 13, 2018
(86) PCT No.: PCT/KR2018/002951

§ 371 Date: Sep. 7, 2018

(30) Foreign Application Priority Data
Sep. 11, 2017 (KR) 10-2017-0115916

(51) Int. Cl. H01L 35/04; H01L 35/24

(52) U.S. Cl. CPC H01L 35/04; H01L 35/24

(57) ABSTRACT

A self-generation sensor device and a self-generation sensor system using the same are disclosed. According to one embodiment, the self-generation sensor device may include: a sensor unit; a communication unit configured to transmit data reflecting a sensed value of the sensor unit; and a thermal power generation module including a pair of main surfaces including a high-temperature surface thermally connected to the high-temperature object and a low-temperature surface which is a surface opposite to the high-temperature surface, a thermoelectric module including a plurality of thermoelectric elements disposed between the pair of main surfaces and producing the power by using a temperature difference between the both main surfaces due to the high-temperature object, and a support member filled in a space between the both main surfaces to support the thermoelectric elements, and a heat dissipation member connected to the low-temperature surface.

### TECHNICAL FIELD

The present invention relates to a self-generation sensor device and a self-generation sensor system using the same, and more particularly, to a self-generation sensor device which is driven by using power produced by performing self-generation as driving power and detects a state of a subject, and a self-generation sensor system using the same.

### BACKGROUND ART

Sensor devices may sense a state of a surrounding environment to provide objective data related to the state of the surrounding environment to a user of the sensor devices.

Particularly, the sensor devices may be used for sensing a state of a subject and detecting the presence or absence of defects in the subject. In relation to this, a Smart Factory requires the sensor devices to be provided to automatically detect the presence or absence of defects in various devices or equipment installed in the factory. The Smart Factory is designated as a next-generation technology, and developments of the Smart Factory is being actively carried out, and in response to this, a demand for the sensor devices is also increasing.

However, a burden of producing power required to operate the sensor devices in the Smart Factory is great. This is because the sensor devices should be provided corresponding to all the devices or equipment provided in the Smart Factory and driving power for driving the provided sensor devices should be supplied to each of the sensor devices. Accordingly, a demand for a self-generation sensor device, which is driven by using power produced by performing self-generation, to alleviate an operational burden is recently increased.

### DISCLOSURE

### Technical Problem

An objective is to provide a self-generation sensor device using power produced by performing self-generation as driving power to alleviate an operational burden and a self-generation sensor system using the same.

Another objective is to provide a self-generation sensor device which produces power by performing self-generation and simultaneously senses a state of a subject on the basis of the produced power, and a self-generation sensor system using the same.

Technical objectives are not limited to the above-mentioned objectives, and objectives not mentioned above should be clearly understood by those skilled in the art to which the present application belongs from the present specification and the accompanying drawings.

### Technical Solution

An embodiment of the present invention is directed to providing a self-generation sensor device which is installed on a high-temperature object and uses power produced by performing self-generation as driving power, the self-generation sensor device including: a sensor unit; a communication unit configured to transmit data reflecting a sensed value of the sensor unit; and a thermal power generation module including a pair of main surfaces including a high-temperature surface thermally connected to the high-temperature object and a low-temperature surface which is a surface opposite to the high-temperature surface, a thermoelectric module including a plurality of thermoelectric elements disposed between the pair of main surfaces and producing the power by using a temperature difference between the both main surfaces due to the high-temperature object, and a support member filled in a single form in a space between the both main surfaces to support the thermoelectric elements, and a heat dissipation member connected to the low-temperature surface, wherein the support member is provided as an insulating material that concentrates the temperature difference between the both main surfaces among heat transmission paths from the high-temperature object to outside air through the thermal power generation module.

Another embodiment of the present invention is directed to providing a self-generation sensor device which is installed in a subject and detects temperature information on the subject on the basis of power produced by performing self-generation, the self-generation sensor device including: a thermal power generation module including a pair of main surfaces including a high-temperature surface thermally connected to the subject and a low-temperature surface which is a surface opposite to the high-temperature surface, a thermoelectric module including a plurality of thermoelectric elements disposed between the pair of main surfaces and producing the power by using a temperature difference between the both main surfaces due to the subject, a support member filled in a single form in a space between the main surfaces to support the thermoelectric elements, and a heat dissipation member connected to the low-temperature surface; and a controller configured to generate state data related to a temperature state of the subject on the basis of electrical characteristics of the power produced by the thermoelectric module.

Solutions to the problem are not limited to the above-mentioned solutions, and solutions not mentioned above should be clearly understood by those skilled in the art to which the present application belongs from the present specification and the accompanying drawings.

### Advantageous Effects

A self-generation sensor device using power produced by performing self-generation as driving power to alleviate an operational burden and a self-generation sensor system using the same can be provided.

A self-generation sensor device which produces power by performing self-generation and simultaneously senses a state of a subject on the basis of the produced power, and a self-generation sensor system using the same can be provided.

The effects are not limited to the above-described effects, and the effects not mentioned may be clearly understood by those skilled in the art to which the present application belongs from the present specification and the accompanying drawings.

### DESCRIPTION OF DRAWINGS

FIG. 1 is a view illustrating a self-generation sensor system according to one embodiment.

FIG. 2 is a view illustrating components of a self-generation sensor device according to one embodiment.

FIG. 3 is an exploded perspective view illustrating a thermal power generation module according to one embodiment.

FIG. 4 is a side view illustrating a thermoelectric module according to one embodiment.

FIG. 5 is a view illustrating a heat dissipation member according to one embodiment.

FIG. 6 is a view illustrating the thermal power generation module according to one embodiment, which is disposed on a high-temperature object.

FIG. 7 is a cross-sectional view illustrating the thermoelectric module according to one embodiment.

FIG. 8 is a view illustrating adjustment of an insulation rate according to one embodiment.

FIG. 9 is a view illustrating a thermal conduction path through the thermal power generation module and thermal resistance of each component of the thermal power generation module according to one embodiment.

FIG. 10 is a graph illustrating a temperature gradient of the thermal power generation module according to one embodiment.

FIG. 11 is a view illustrating thermal conduction through a thermoelectric module and thermal resistance of the thermoelectric module according to one embodiment.

FIG. 12 is a graph illustrating a relationship between an insulation rate(IR), a thermoelectric temperature difference(ΔT_{TE}), and a thermoelectric area according to one embodiment.

FIG. 13 is a graph illustrating an amount of power according to the insulation rate(IR) according to one embodiment.

FIG. 14 is a view illustrating a current generated in the thermoelectric module according to one embodiment.

FIG. 15 is a flowchart of a sensing method of the self-generation sensor device according to one embodiment.

### BEST MODE

According to one embodiment, there is provided a self-generation sensor device which is installed on a high-temperature object and uses power produced by performing self-generation as driving power, the device including: a sensor unit; a communication unit configured to transmit data reflecting a sensed value of the sensor unit; and a thermal power generation module including a pair of main surfaces including a high-temperature surface thermally connected to the high-temperature object and a low-temperature surface which is a surface opposite to the high-temperature surface, a thermoelectric module including a plurality of thermoelectric elements disposed between the pair of main surfaces and producing the power by using a temperature difference between the both main surfaces due to the high-temperature object, and a support member filled in a single form in a space between the both main surfaces to support the thermoelectric elements, and a heat dissipation member connected to the low-temperature surface, wherein the support member is provided as an insulating material that concentrates the temperature difference between the both main surfaces among heat transmission paths from the high-temperature object to outside air through the thermal power generation module.

### Modes of the Invention

Since embodiments described herein are for clearly explaining the idea of the present application to those skilled in the art to which the present application belongs, the present application is not limited to the embodiments described herein, and the scope of the present application should be understood as including changed examples and modified examples without departing from the spirit of the present application.

Although terms provided herein are selected from general terms which are currently widely used in consideration of functions of the present application, which may vary depending on an intention or custom of those skilled in the art to which the present application belongs, or the emergence of new technology. However, unlike this, when specific terms are defined and used as arbitrary meanings, the meanings of the terms will be described separately. Accordingly, the terms used herein should be understood on the basis of actual meanings of the terms rather than on names of the simple terms, and on contents of the description throughout this specification.

Drawings attached hereto are intended to easily explain the description of the present application, and shapes shown in the drawings may be illustrated in an exaggerated way as necessary to aid in understanding of the present application, and thus the present application is not limited to the drawings

In the present specification, when it is determined that detailed descriptions of related well-known functions or configurations unnecessarily obscure the gist of the present application, the detailed descriptions thereof will be omitted as necessary.

According to one embodiment, there is provided a self-generation sensor device which is installed on a high-temperature object and uses power produced by performing self-generation as driving power, the self-generation sensor device including: a communication unit configured to transmit data reflecting a sensed value of the sensor unit; and a thermal power generation module including a pair of main surfaces including a high-temperature surface connected to the high-temperature object and a low-temperature surface which is a surface opposite to the high-temperature surface, a thermoelectric module including a plurality of thermoelectric elements disposed between the pair of main surfaces to form a two-dimensional array when viewed in a direction perpendicular to the main surface and producing the power by using a temperature difference between the both main surfaces due to the high-temperature object, and a support member filled in a space between the both main surfaces to support the thermoelectric elements, and a heat dissipation member connected to the low-temperature surface, wherein the support member is provided as an insulating material that concentrates the temperature difference between the both main surfaces among heat transmission paths from the high-temperature object to outside air through the thermal power generation module.

Herein, there may be provided the self-generation sensor device in which a ratio of an area occupied by the support member to an area occupied by the plurality of thermoelectric elements on the main surface is 5 or more so that generation efficiency of each of the plurality of thermoelectric elements increases as the temperature difference is concentrated between the both main surfaces.

Herein, there may be provided the self-generation sensor device in which the area occupied by the plurality of thermoelectric elements 130 to the area occupied by the support member on the main surface is at least 10% or more so that a generation area of the thermoelectric elements 130 for performing power generation by the temperature difference applied between the both main surfaces becomes sufficient.

Herein, there may be provided the self-generation sensor device in which the support member includes bubbles so that the temperature difference is further concentrated between the both main surfaces.

Herein, there may be provided the self-generation sensor device in which an arrangement member configured to diffuse heat in a surface direction is disposed between the thermoelectric module and the heat dissipation member so that the heat of the low-temperature surface is decreased and thus the temperature difference is further concentrated between the both main surfaces.

Herein, there may be provided the self-generation sensor device in which a contact surface coming into contact with the high-temperature object is formed on the low-temperature surface, and an adhesive property is imparted to the contact surface.

Herein, there may be provided the self-generation sensor device in which a contact surface coming into contact with the high-temperature object is formed on the low-temperature surface, and an adhesive property is imparted to the contact surface.

Herein, there may be provided the self-generation sensor device in which, when the thermoelectric module is disposed on a curved surface of the high-temperature object, the thermoelectric module having a curvature corresponding to the curved surface is disposed on the curved surface so that there is no separated space between the curved surface and the low-temperature surface.

Herein, there may be provided the self-generation sensor device in which, when the thermoelectric module is disposed on a curved surface of the high-temperature object, the thermoelectric module having a curvature corresponding to the curved surface is disposed on the curved surface so that there is no separated space between the curved surface and the low-temperature surface.

Herein, there may be provided the self-generation sensor device in which a temperature gradient is formed between the low-temperature surface of the thermal power generation module and an end of a heat dissipation element in a steady state in which an amount of the heat transmitted from the high-temperature object to the thermoelectric module is identical to an amount of the heat emitted from the heat dissipation element to the outside air, and wherein the temperature gradient is suddenly changed in the thermoelectric module due to a reduction in a movement of the heat conducted through the thermoelectric module by the support member.

Herein, there may be provided the self-generation sensor device in which the ratio of the area occupied by the support member to the area occupied by the plurality of thermoelectric elements on the main surface is 5 or more so that the temperature gradient in the thermoelectric module is suddenly changed.

Herein, there may be provided the self-generation sensor device in which the ratio of the area occupied by the support member to the area occupied by the plurality of thermoelectric elements on the main surface is 9 or less so that an allowable amount of current of the thermoelectric elements for performing power generation by the temperature gradient becomes sufficient.

According to another embodiment, there may be provided a self-generation sensor device installed in a subject and detects temperature information on the subject on the basis of power produced by performing self-generation, the device including: a thermal power generation module including a pair of main surfaces including a high-temperature surface connected to the high-temperature object and a low-temperature surface which is a surface opposite to the high-temperature surface, a thermoelectric module including a plurality of thermoelectric elements disposed between the pair of main surfaces to form a two-dimensional array when viewed in a direction perpendicular to the main surface and producing the power by using a temperature difference between the both main surfaces due to the high-temperature object, and a support member filled in a space between the both main surfaces to support the thermoelectric elements 130, and a heat dissipation member connected to the low-temperature surface; and a controller configured to generate state data related to a temperature state of the subject based on electrical characteristics of the power produced by the thermoelectric module.

Hereinafter, a self-generation sensor device and a self-generation sensor system including the same will be described.

A connection of one component to another component in this specification should be understood as a concept covering not only that the one component is directly bonded to the other component but also that the one component is bonded to the other component with a certain component interposed between the one component and the other component.

When a one-to-one correspondence is made and thus it is increased or decreased by a, a concept of proportion and inverse proportion in this specification should be understood not only as a concept that is increased or decreased by a in response to the increasing or decreasing, but also as a concept that includes a tendency to be proportional or inversely proportional to each other.

### 1. Self-Generation Sensor System

A self-generation sensor system according to one embodiment may be a system which senses states of various devices and provides the detected states of the various devices to a user. The sensing of the states of the various devices, which is performed by the self-generation sensor system, may be performed using power produced by the system by performing self-generation.

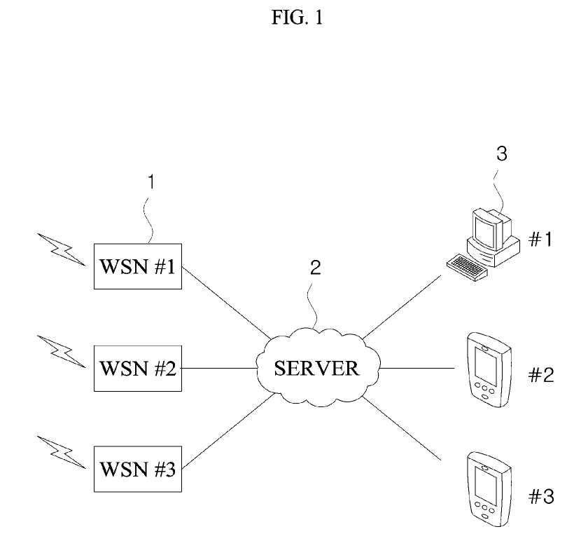

FIG. 1 is a view illustrating a self-generation sensor system according to one embodiment.

Referring to FIG. 1, the self-generation sensor system may include a self-generation sensor device 1, a server 2, and a user terminal. However, the present invention is not limited to the above-described components, and the self-generation sensor system may be configured as a system having more or fewer components than the above-described components. For example, the self-generation sensor system may include only the self-generation sensor device 1 and the user terminal without the server 2 or may include only the self-generation sensor device 1 and the server 2 without the user terminal.

The self-generation sensor device 1 may sense the states of the various devices using the power produced by performing the self-generation. Herein, the sensed state may be a defect of an apparatus on which the self-generation sensor device 1 is disposed.

The server 2 may acquire state data on the states of the various devices from the self-generation sensor device 1, and integrate and manage the data.

The user terminal may receive the state data from the server 2 and may provide the state data to users who use the user terminal. Specifically, the user terminal may provide current states of the various apparatus in a facility to the users of the user terminal on the basis of the state data.

Hereinafter, the self-generation sensor device 1 will be described in more detail. Meanwhile, the server 2 and the user terminal may be implemented with a device which may be normally used. Therefore, a detailed description of the server 2 and the user terminal will be omitted.

On the other hand, the present invention is not limited thereto, and the self-generation sensor device 1 may directly communicate with personal terminals 3. In this case, an application configured to directly communicate with the self-generation sensor device 1 may be provided in the personal terminal 3 to perform data exchange, or the data exchange may be performed by browser communication such as WebRTC by which the data may be directly exchanged even without a separate application.

### 2. Self-Generation Sensor Device

The self-generation sensor device 1 according to one embodiment is a device configured to perform self-generation, sensing, and deliver data of the sensed result to external devices.

### 2.1 Summary of Self-Generation Sensor Device

A self-generation sensor device 1 is a device which uses power which is produced by performing the self-generation as driving power for sensing and operations associated with the sensing. For example, in addition to sensing the states of the various apparatus, the self-generation sensor device 1 may use the produced power to communicate with the external devices.

The self-generation sensor device 1 may be attached to and installed on various apparatus, equipment, or the like, and receive heat emitted from the various apparatus, equipment, or the like to perform the self-generation. For example, the self-generation sensor device 1 may be installed in the device or equipment such as a heat pipe in a factory facility for the self-generation.

The heat applied from the various apparatus or equipment may be converted into the power by a thermoelectric element 130 provided in the self-generation sensor device 1, which may be caused by a temperature difference formed in the self-generation sensor device 1 by the heat. The operation of the thermoelectric element 130 will be described in detail below.

Meanwhile, the heat may include hot heat and cold heat. The temperature difference may be formed in the self-generation sensor device 1 by the hot heat and the cold heat applied to the self-generation sensor device 1, so that the self-generation sensor device 1 may perform the self-generation on the basis of the temperature difference. In other words, the device or equipment on which the self-generation sensor device 1 may be installed to perform the self-generation is not limited to the device or equipment which emits the hot heat, and the device or equipment may be a device or equipment which emits the cold heat as long as the device or equipment is a device or equipment capable of forming the temperature difference.

However, for ease of explanation, the following description will be made assuming that the device or equipment on which the self-generation sensor device 1 is installed is the device or equipment which emits the hot heat. The device or equipment which emits the hot heat may be defined as a high-temperature object.

A self-generation sensor device 1 may perform sensing on the basis of the produced power. An object to be sensed (hereinafter referred to as a subject) may be the high-temperature object on which the self-generation sensor device 1 is installed, but the subject may also be a device or equipment other than the high-temperature object. For example, the self-generation sensor device 1 may be installed on the heat pipe to sense a state of the heat pipe, alternatively, the self-generation sensor device 1 may be installed in the heat pipe to sense a state of a steam trap.

Herein, the sensing may be to sense characteristics of all states of the subject, and the purpose of such a sensing may be to detect the presence or absence of defects such as whether the subject is malfunctioning or not. For example, the self-generation sensor device 1 may sense a temperature state of the heat pipe and detect whether the heat pipe is malfunctioning or not on the basis of the temperature state. The detection of the presence or absence of the defect may be performed in the self-generation sensor device 1 itself, but may also be performed in the server 2 or the personal terminal 3 which receives the state data of the subject from the self-generation sensor device 1.

Hereinafter, the configuration of the self-generation sensor device 1 will be described.

### 2.2 Configuration of Self-Generation Sensor Device

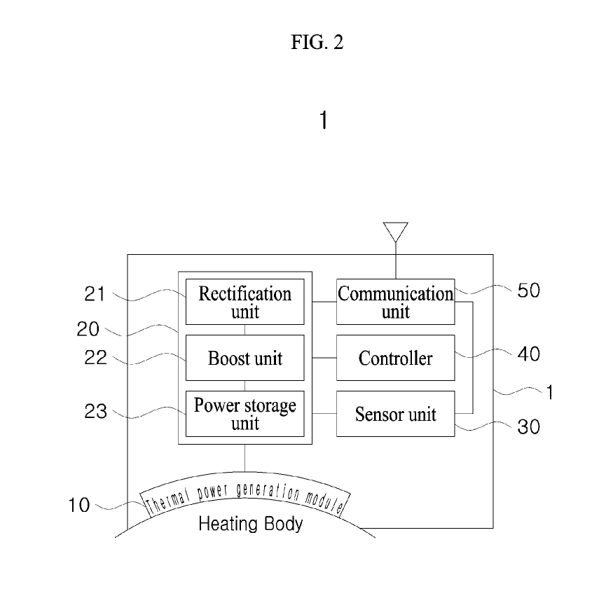

FIG. 2 is a view illustrating components of a self-generation sensor device 1 according to one embodiment.

Referring to FIG. 2, a self-generation sensor device 1 includes a thermal power generation module 10, a power storage module 20, a sensor unit 30, a controller 40, and a communication unit 50, and the power storage module 20 may include a rectification unit, a boost unit, and a power storage unit. However, the present invention is not limited to the configuration illustrated in FIG. 2, and the self-generation sensor device 1 may include more components than those illustrated in FIG. 2.

The thermal power generation module 10 is attached to and disposed on the high-temperature object, and may convert heat emitted from the high-temperature object to power.

The power storage module 20 may store the power produced in the thermal power generation module.

The sensor unit 30 may sense the states of the various apparatus in the facility.

The communication unit 50 may exchange data with the external devices. Particularly, data related to the states of the various apparatus in the facility may be exchanged.

The controller 40 may control the operation of each component of the above-described self-generation sensor device 1.

That is, the self-generation sensor device 1 stores the power produced by the thermal power generation module in the power storage module 20, and at least one of the sensor unit 30, the communication unit 50, and the controller 40 is driven on the basis of the power stored in the power storage module 20, wherein the sensor unit 30 may sense the states of the various apparatus in the facility, and the communication unit 50 may deliver the data generated according to the sensing to the external devices such as the server 2 or the personal terminal 3.

Meanwhile, as illustrated in the drawings, a self-generation sensor device 1 may be disposed on surfaces of various apparatus having curvature, but may also be disposed on flat surfaces of the various apparatus.

Hereinafter, the components will be described. First, a thermal power generation module 10 will be described.

The thermal power generation module 10 according to one embodiment generates the current using the thermoelectric element 130 and may produce the power on the basis of the produced current.

To this end, the thermal power generation module 10 may be connected to the high-temperature object. In other words, the thermal power generation module 10 may be disposed adjacent to the high-temperature object to receive the heat therefrom. A temperature gradient formed in the thermal power generation module 10 by the heat may cause the current to be formed in a thermoelectric module 100, and the generated current may be converted to the power.

The power produced by the thermal power generation module 10 may be transmitted to each component of the self-generation sensor device 1, and the components of the self-generation sensor device 1 may be driven by the transmitted power. That is, the power may be transmitted to at least one of the power storage module 20, the communication unit 50, the controller 40, and the sensor unit 30. To this end, members such as electric wires, or the like may be provided such that the thermal power generation module 10 is electrically connected to the power storage module 20, the communication unit 50, the sensor unit 30, and the controller 40.

Meanwhile, the components driven by the power may use the directly received power as driving power, but the components may also be driven by receiving and using the driving power for driving each component produced by the power.

As described above, since the components are driven by the power produced in the thermal power generation module 10, generation efficiency of the thermal power generation module 10, in other words, power production efficiency of the thermal power generation module 10 may be a major factor in determining a performance index of the self-generation sensor device 1. For example, when the generation efficiency of the thermal power generation module 10 is improved, the power storage module 20, the communication unit 50, the sensor unit 30, or the controller 40 having further improved performance may be provided in the self-generation sensor device 1. The performance of the self-generation sensor device 1 may be improved due to the components having the improved performance.

Therefore, it is necessary to maximize the generation efficiency or power production efficiency of the thermal power generation module 10, which will be described in detail below.

Hereinafter, a power storage module 20 will be described.

A power storage module 20 according to one embodiment may store the power produced by the thermal power generation module 10.

Referring again to FIG. 2, the power storage module 20 may include a power storage unit 23, a boost unit 22, and a rectification unit 21. However, the present invention is not limited to the configuration illustrated in FIG. 2, and the power storage module 20 may include more or fewer components than those illustrated in FIG. 2.

The power storage unit 23 may be defined as a component which stores power applied to the power storage module 20. The boost unit 22 may be defined as a component which allows the power applied to the power storage module 20 to be stably stored in the power storage module 20. The rectification unit 21 may be defined as a component which stabilizes the power applied to or output from the power storage module 20.

Hereinafter, components of the power storage module 20 will be described.

The power storage unit 23 may store the power produced by the thermal power generation module 10. The power storage unit 23 may be provided as a battery such as a storage device or a lithium battery, and accordingly, the power storage unit 23 may be expressed as charging the power.

When the power is stored in the power storage unit 23, the boost unit 22 may be provided so that the power is stably stored in the power storage unit 23. The boost unit 22 is electrically connected simultaneously to both the thermal power generation module 10 and the power storage unit 23 and may receive the current or power output from the thermal power generation module 10. The boost unit 22 may quickly rectify the received current or power and thus the current or power may be quickly and stably charged in the power storage unit 23.

The power stored in the power storage unit 23 may be transmitted to other components when the other components need the power. When the power is transmitted, the power may be transmitted to the other components through the rectification unit 21. Like the above-described boost unit 22, the rectification unit 21 may receive and stabilize the current or power and then output the current or power. The stabilization may mean reducing a magnitude of the power to be output, or reducing a change in the magnitude of the power.

The rectification unit 21 may be, for example, a regulator. A type of the regulator may include i) a linear regulator which has a form of directly adjusting the supplied power and ii) a switching regulator which generates a pulse on the basis of the supplied power and outputs a precisely adjusted voltage by adjusting an amount of the pulse.

That is, in the power storage module 20, the power produced from the thermal power generation module 10 is applied to the boost unit 22, stored in the power storage unit 23 in a stable and prompt manner, and rectified through the rectification unit 21 to output to the components requiring the power. For example, the power storage module 20 may transmit the power to at least one of the sensor unit 30, the communication unit 50, and the controller 40.

A sensor unit 30 according to one embodiment may sense the states of the various apparatus in the facility. That is, the sensor unit 30 may generate the state data related to the subject.

The sensor unit 30 may be implemented as a multi-sensor type which measures various states of the subject, or a single sensor type which measures only one state of the subject.

When the sensor unit 30 is implemented as the multi-sensor type, most of the states and characteristics related to the subject are sensed, so that state data reflecting the sensed states and characteristics may be generated. For example, the state data may include data on a humidity value, a temperature value, the presence or absence of gas, or the like related to the subject. To this end, various sensor elements may constitute the sensor unit 30 all at once. The various sensors may include a temperature sensor configured to sense temperature, a humidity sensor configured to sense humidity, and a gas sensor configured to detect the presence or absence of gas.

When the sensor unit 30 is implemented as the multi-sensor type, the sensor unit 30 may reliably diagnose the presence or absence of the defects in the subject. Most of the states and characteristics of the subject may be grasped by implementing the sensor unit 30 as a multi-type so that probability of erroneous detection of the defects in the subject is reduced.

When the sensor unit 30 is implemented as the single sensor type, only some of the states and characteristics related to the subject may be sensed, and state data related to some may be generated. For example, when a temperature sensor is constituted by the single sensor, the sensed value may include data on a temperature value related to the subject. In this case, one sensor element among the various sensor elements described above may be selected to implement the sensor unit 30.

When the sensor unit 30 is implemented as the single sensor type, the burden of operating the self-generation sensor device 1 may be alleviated.

A communication unit 50 according to one embodiment may allow the thermal power generation module 10 to communicate with external devices such as other electronic devices and/or the server 2.

A communication unit 50 may include one or more modules for enabling the communication. A communication unit 50 may communicate with the external devices in a wired manner or may communicate with the external devices in a wireless manner. In other words, the self-generation sensor device 1 may communicate with the server 2 and/or the personal terminal 3 in the wireless manner or in the wired manner.

To this end, the communication unit 50 may include a wired communication module for connecting to the Internet or the like through a local area network (LAN), a mobile communication module such as a long term evolution (LTE) or the like which accesses a mobile communication network through a mobile communication base station to transmit/receive data, a near-field communication module which uses a wireless local area network (WLAN) based communication method such as Wi-Fi and a wireless personal area network (WPAN) based communication method such as Bluetooth and Zigbee, and a satellite communication module which uses a global navigation satellite system (GNSS) such as a global positioning system (GPS), or a combination thereof.

Meanwhile, the communication unit 50 may be implemented as a communicator capable of performing a long-range (LoRa) communication. Accordingly, the communication unit 50 allows the self-generation sensor device 1 to perform long-distance communication with low power. That is, when the self-generation sensor device 1 is provided in various facilities and exchanges predetermined data with a remote server or a personal terminal, repeaters located between the self-generation sensor device and the server or personal terminal need not be used. In other words, even when the repeaters are not provided, the self-generation sensor device may directly exchange the predetermined data with the server or personal terminal on the basis of the LoRa communication. As a result, a loss rate of the data transmitted from the self-generation sensor device 1 may be reduced, and an incidence of problems such as modulation of the transmitted data may be reduced.

A controller 40 according to one embodiment may be generally involved in operations of the components of the thermal power generation module 10. Accordingly, the operation of the thermal power generation module 10 may be understood as being performed by the controller 40 unless otherwise specified.

The controller 40 may be implemented as a computer or similar device based on hardware, software, or a combination thereof. In terms of the hardware, the controller 40 may be provided in the form of an electronic circuit including CPUs, MCUs, chips, or the like which processes electric signals to perform a control function, and in terms of the software, the controller 40 may be provided in the form of a program which drives the hardware of the controller 40.

As described above, the thermal power generation module 10 is configured to produce the power such that the components of the self-generation sensor device 1 are driven. The thermal power generation module 10 may have predetermined physical components and may be implemented with a predetermined structure, so that the power may be produced. Hereinafter, the thermal power generation module 10 will be described in more detail.

### 3. Thermal Power Generation Module

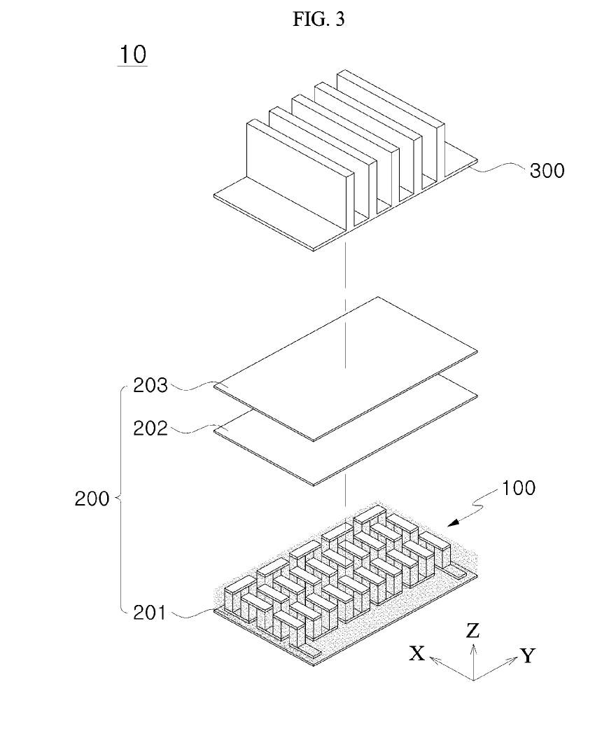

FIG. 3 is an exploded perspective view illustrating the thermal power generation module 10 according to one embodiment.

Referring to FIG. 3, the thermal power generation module may include a thermoelectric module 100 and a heat dissipation member 300, and an arrangement member 200 disposed by being brought into contact with the thermoelectric module 100 and the heat dissipation member 300 may be provided. However, the present invention is not limited to the components illustrated in FIG. 3 and the thermoelectric module may also be implemented with a thermoelectric module having more or fewer components. For example, in FIG. 3, although two layers of the arrangement member 200 are illustrated as being disposed between the thermoelectric module 100 and the heat dissipation member 300, more than two layers of the arrangement member 200 or fewer than two layers of the arrangement member 200 may also be disposed on the thermoelectric module.

The thermoelectric module 100 may be disposed on the high-temperature object and may perform the power generation to produce the power.

The heat dissipation member 300 may be connected to and disposed on the thermoelectric module 100 and may emit the heat.

The various arrangement members 200 may be disposed by being brought into contact with upper and lower portions of the thermoelectric module 100. The various arrangement members 200 may include an arrangement member 200 which is close to the heat dissipation member 300 and disposed to form certain layers on a surface of the thermoelectric module 100, and an arrangement member 200 which is farther from the heat dissipation member 300 and disposed on the surface of the thermoelectric module 100.

That is, the thermal power generation module may include the thermoelectric module 100 bonded to the high-temperature object and the various arrangement members 200 disposed on the thermoelectric module 100, and may include the heat dissipation member 300 for emitting the heat from the thermoelectric module 100. The heat emitted from the high-temperature object is transmitted to the thermal power generation module and emitted through the heat dissipation member 300, and the thermoelectric module 100 may perform the power generation on the basis of the transmitted heat to produce the power.

Hereinafter, each component will be described in detail.

### 3.1 Thermoelectric Module

A thermoelectric module 100 may be basically provided in the form of a flat plate. Herein, a thermoelectric module 100 may have flexibility and thus may be deformed into a curved surface shape. A thermoelectric module 100 in the form of the flat plate may have two main surfaces. A thermoelectric module 100 may produce electricity using a temperature difference generated between the two main surfaces.

The thermoelectric module 100 may receive the heat from the high-temperature object at one main surface disposed adjacent to the high-temperature object among the two main surfaces. The temperature difference due to the applied heat may be used to produce the power by performing the self-power generation. In other words, the thermoelectric module 100 is disposed on the high-temperature object and may produce the power on the basis of the temperature difference due to the heat applied from the high-temperature object.

The two main surfaces may be defined as two surfaces of the thermoelectric module 100. The two main surfaces may be surfaces physically or virtually defined in the thermoelectric module 100. The two main surfaces may be two physical surfaces of the thermoelectric module 100 when the thermoelectric module 100 is separated from the thermoelectric module 10 and observed. Alternatively, the two main surfaces may be defined as virtual surfaces separating the thermoelectric module 100 from the arrangement member 200 disposed adjacent to the thermoelectric module 100 or the heat dissipation member 300 when the thermal power generation module 10 is disposed.

The two main surfaces may have one surface which may be a high-temperature surface 101 and the other surface which may be a low-temperature surface 103.

When the thermoelectric module 100 is disposed on the high-temperature object, the high-temperature surface 101 may be defined as a surface of the thermoelectric module 100, which is located adjacent to the high-temperature object, and the low-temperature surface 103 may be defined as a surface located opposite to the high-temperature surface 101 of the thermoelectric module 100.

The high-temperature surface 101 may be defined as a surface located opposite to the low-temperature surface 103 of the thermoelectric module 100. In other words, the high-temperature surface 101 may face the low-temperature surface 103.

The low-temperature surface 103 may be defined as the surface of the thermoelectric module 100, which is adjacent to the heat dissipation element 321 and 323.

Hereinafter, a layer structure of the thermoelectric module 100 will be described.

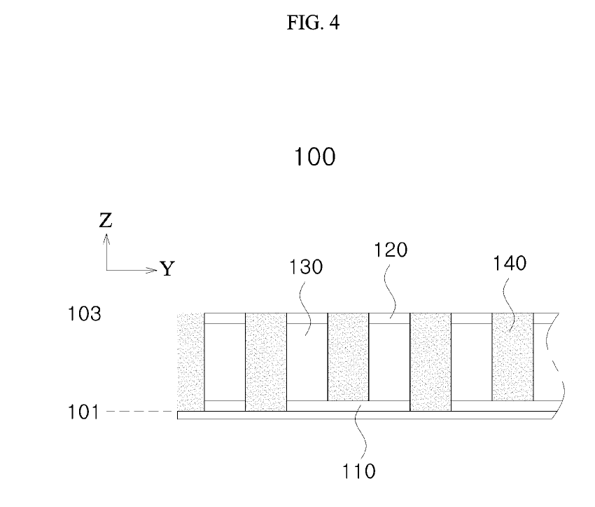

FIG. 4 is a side view illustrating the thermoelectric module 100 according to one embodiment.

Referring to FIG. 4, the thermoelectric module 100 may include the thermoelectric element 130 disposed between two main surfaces, a conductor member 110 and 120 including a first conductor member 110 and a second conductor member 120 which are brought into contact with the thermoelectric element 130, and a support member 140.

Herein, the thermoelectric element 130 may perform a thermoelectric operation to produce the electricity, and the conductor member may be electrically connected to the thermoelectric element 130 to transmit the produced electricity to the outsides, and the support member 140 may be filled in a space between the two main surfaces. As an example, the support member 140 may be filled in a single form in the space between the two main surfaces to support the thermoelectric element 130.

Hereinafter, each component of the thermoelectric module 100 disposed between the two main surfaces will be described in detail with reference to FIG. 4.

### 3.1.1 Thermoelectric Element and Conductor Member between Two Main Surfaces

The thermoelectric element 130 and the conductor member 110 and 120 may be disposed between the two main surfaces of the thermoelectric module 100.

The thermoelectric element 130 may be provided as a semiconductor member, and the semiconductor member may include an N-type semiconductor and a P-type semiconductor. That is, the N-type semiconductor and the P-type semiconductor may be disposed between the two main surfaces. The N-type semiconductor and the P-type semiconductor may be disposed alternately with each other.

The conductor member may connect the semiconductor members. The conductor member may include a first conductor member 110 and a second conductor member 120. The first conductor member 110 may be defined as a conductor member coming into contact with the high-temperature surface 101 and the second conductor member 120 may be defined as a conductor member coming into contact with the low-temperature surface 103.

The conductor member may include a material which electrically connects the thermoelectric element 130.

The thermoelectric element 130 and the conductor member may be disposed such that the thermoelectric element 130 and the conductor member are formed in a two-dimensional array when observed from a direction perpendicular to the main surfaces.

The thermoelectric module 100 including the thermoelectric element 130 and the conductor member may produce the power on the basis of a temperature difference ΔT_{TE} between the two main surfaces.

The current may be generated in the thermoelectric element 130 and the conductor member on the basis of the temperature difference ΔT_{TE} between the two main surfaces. Accordingly, the thermoelectric element 130 may produce the power.

Electrons are moved to the N-type semiconductor on the basis of the temperature difference ΔT_{TE} between the two main surfaces, and a current may flow in a direction opposite to the direction of an electron movement. Specifically, when the thermoelectric module 100 is disposed on the high-temperature object, the electrons move on the basis of the temperature difference between the high-temperature surface 101 and the low-temperature surface 103 to cause the current to flow, and the movement direction of the electrons is determined in a direction toward the low-temperature surface 103. On the contrary, in the P-type semiconductor, electrons move in the direction toward the high-temperature surface 101.

The current formed in the thermoelectric element 130 moves along the conductor member, and the current flows to the entire thermoelectric module 100.

The current formed in the entire thermoelectric module 100 may be converted to the power. As a result, since the current generated in the thermoelectric element 130 on the basis of the temperature difference ΔT_{TE} between the two main surfaces is converted to the power, it may be said that the thermoelectric element 130 produces the power on the basis of the temperature difference ΔT_{TE} between the two main surfaces.

Meanwhile, the produced power may be used i) as driving power for each component of the thermal power generation module 10, or ii) to sense the temperature of various apparatus in the facility. This will be explained in detail.

### 3.1.2 Support Member between Two Main Surfaces

A support member 140 may be filled in the space between the two main surfaces of the thermoelectric module 100. As an example, a support member 140 may be filled in the single form in the space between two main surfaces. A support member 140, which is filled in the space between the two main surfaces, may support the thermoelectric module 100 to improve the electrical stability of the thermoelectric module 100 and may increase thermal resistance RTE of the thermoelectric module 100.

A support member 140, which is filled in the space between the two main surfaces, may impart flexibility to a thermoelectric module 100.

Accordingly, when the thermoelectric module 100 is bent due to an external force, a support member 140 may also be bent according to the bent. At the same time, the support member 140 may support the bent thermoelectric element 130. Specifically, the support member 140, which is filled in the space between the two main surfaces, is brought into contact with the thermoelectric element 130, and may support the thermoelectric element 130 by maintaining the contacting relationship even when the thermoelectric module 100 is bent.

Accordingly, the support member 140 supports the thermoelectric element 130 deformed by receiving the external force, and thus the destruction of the thermoelectric element 130 due to the deformation may be prevented. As a result, since the support member 140 include a flexible material, flexibility may be imparted to the thermoelectric module 100 and toughness of the thermoelectric module 100 against the external force may be improved.

As described above, the support member 140 may include a flexible material to impart the flexibility to the thermoelectric module 100.

Also, the support member 140 may impart an electrical insulation property to the thermoelectric module 100. Specifically, the first conductor member 110, the thermoelectric element 130, and the second conductor member 120 of the thermoelectric module 100, which are adjacent to each other, may be electrically insulated from each other.

To this end, the support member 140 may include an electrically insulating material. Accordingly, an electrical short circuit between the thermoelectric elements 130 may be prevented by the support member 140, so that the electrical stability of the thermoelectric module 100 may be improved. When the support member 140 is not filled in the space between the two main surfaces, a current flowing along the thermoelectric element 130 and the conductor member between the two main surfaces may be applied to other adjacent thermoelectric elements 130 and other adjacent conductor members. In this case, the thermoelectric module 100 is electrically short-circuited to malfunction. On the other hand, when the support member 140 is filled in the space between the two main surfaces, the thermoelectric elements 130 or the conductor members, which are adjacent to each other, may be insulated from each other. Accordingly, the thermoelectric module 100 may be electrically stabilized.

Further, the support member 140 may impart thermal insulation properties to the thermoelectric module 100.

The support member 140 may include a thermally insulating material. The support member 140 including the thermally insulating material may have a very high thermal resistance. The thermal resistance of the support member 140 may be thermal resistance close to the thermal resistance of the air.

Accordingly, the thermal resistance RTE of the thermoelectric module 100 may be increased on the basis of the support member 140 filled in the space between the two main surfaces.

The thermal resistance RTE of the thermoelectric module 100 may be determined on the basis of the thermal resistance of the thermoelectric element 130 and the thermal resistance of the support member 140. The thermal resistance RTE of the thermoelectric module 100 may be increased as the thermal resistance of the thermoelectric element 130 is increased and the thermal resistance of the support member 140 is higher than that of the thermoelectric element 130.

The thermal resistance of the thermoelectric element 130 may be increased as an area S_{TE} of the thermoelectric element 130 decreases by filling the support member 140. The increased thermal resistance of the thermoelectric element 130 may be caused by the relational expression: R=p^{1/A} (where p is thermal resistivity, A is an area, and 1 is a thickness).

Further, the thermal resistance of the support member 140 may be greater than that of the thermoelectric element 130.

Accordingly, the overall thermal resistance RTE of the thermoelectric module 100 may be increased.

Power generation efficiency of the thermoelectric element 130 may be improved as the thermal resistance RTE of the thermoelectric module 100 is increased, which will be described in detail below.

Further, the support member 140 may include a material containing bubbles. The flexibility, the electrical insulation properties, and the thermal resistance of the support member 140 may be further improved by the bubbles. When the support member 140 containing the bubbles receives an external force, the support member 140 may have a property of being more easily bent by the external force. Further, conduction paths of the heat passing through the support member 140 may be short-circuited by the bubbles contained in the support member 140. In other words, since the movement of heat passing through the support member 140 may be blocked by the bubbles contained in the support member 140, the thermal resistance of the support member 140 may be improved.

One example of the support member 140 may be polyurethane (PU), but the support member 140 may include a material which is not limited thereto.

Hereinafter, a heat dissipation member 300 will be described.

### 3.2 Heat Dissipation Member

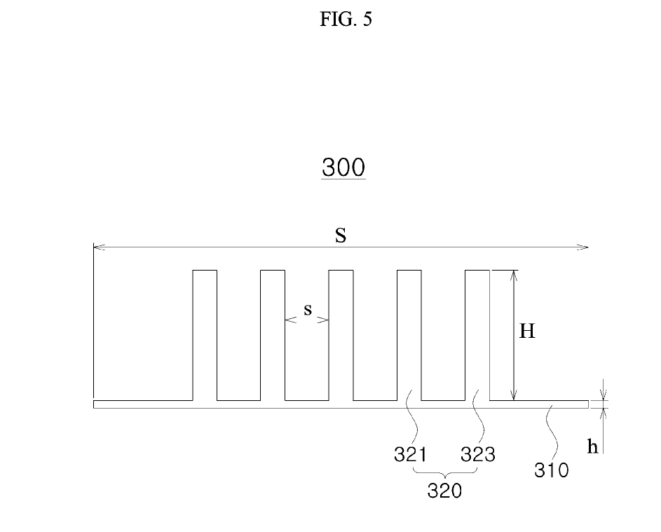

FIG. 5 is a view illustrating a heat dissipation member 300 according to one embodiment.

The following description will be made with reference to FIGS. 4 and 5.

A heat dissipation member 300 according to one embodiment is connected to the thermoelectric module 100 and may thermally protect the thermoelectric module 100. Specifically, the heat dissipation member 300 may be connected to the low-temperature surface 103 of the thermoelectric module 100.

The heat dissipation member 300 may decrease the heat accumulated in the thermoelectric module 100. The heat dissipation member 300 may emit waste heat accumulated in the thermoelectric module 100 by allowing the heat of the thermoelectric module 100 to be emitted to the outside. The heat dissipation member 300 may decrease the heat accumulated on the low-temperature surface 103 of the thermoelectric module 100.

Due thereto, power generation efficiency of the thermoelectric module 100 may be improved. The thermoelectric module 100 may produce the power on the basis of the temperature difference ΔT_{TE} between the high-temperature surface 101 and the low-temperature surface 103. The temperature difference ΔT_{TE} between the high-temperature surface 101 and the low-temperature surface 103 may be a first temperature difference ΔT_{TE} when the heat dissipation member 300 is disposed without being connected to the thermoelectric module 100. When the heat dissipation member 300 is disposed by being connected to the thermoelectric module 100, the heat accumulated on the low-temperature surface 103 may be decreased by the heat dissipation member 300. In this case, the temperature difference ΔT_{TE} between the high-temperature surface 101 and the low-temperature surface 103 may be a second temperature difference ΔT_{TE}. The second temperature difference ΔT_{TE} may be greater than the first temperature difference ΔT_{TE}. As a result, the power generation efficiency of the thermoelectric module 100 may be improved when the heat dissipation member 300 is disposed thereon.

Hereinafter, components of a heat dissipation member 300 will be described.

The heat dissipation member 300 may include a body 310 and a heat dissipation element 321 and 323.

The body 310 may be a base on which the heat dissipation member 300 is formed.

The heat dissipation element 321 and 323 may extend from the body 310 to radiate the heat of the heat dissipation element 321 and 323.

The body 310 and the heat dissipation element 321 and 323 may be formed to have a suitable thickness according to the purpose of implementation.

The body 310 and the heat dissipation element 321 and 323 may have a structure and a thickness to efficiently decrease the heat accumulated on the low-temperature surface 103 of the thermoelectric module 100. In order to efficiently lower the heat, the body 310 may be implemented to be thin and the heat dissipation element 321 and 323 may extend to have a long length.

Further, the body 310 and the heat dissipation member 300 may be formed of a suitable material according to the purpose of implementation. The body 310 may be formed of a material having high thermal diffusivity in a surface direction so that the heat applied to the body 310 is diffused in the surface direction. The heat dissipation member 300 may be formed of a material having high thermal diffusivity in a vertical direction so that the heat applied to the heat dissipation member 300 is emitted to the outside air.

Further, the body 310 and the heat dissipation member 300 may be provided in suitable shapes according to the purpose of implementation, without being limited to the illustrated shapes. The body 310 may be provided in a square pillar shape as illustrated in the drawings, but the present invention is not limited thereto, and the body 310 may be provided in various polygonal pillar shapes such as a circle, a semicircle, a triangle shape, and the like or in a pillar shape having a combination of the polygonal shapes. The heat dissipation member 300 may extend from the body 310 in a rectangular plate shape as illustrated in the drawings, but the present invention is not limited thereto, and the heat dissipation member 300 may extend from the body 310 in various shapes such as a cylindrical shape, and the like.

Hereinafter, an arrangement member 200 will be described.

### 3.3 Various Arrangement Members

Various arrangement members 200 according to one embodiment may be disposed by being brought into contact with the thermoelectric module 100. The arrangement members 200 may include a certain arrangement member 200 (hereinafter referred to as a first arrangement member 201) disposed on the high-temperature surface 101 of the thermoelectric module 100, and a certain arrangement member 200 (hereinafter referred to as a second arrangement member 202 and 203) disposed on the low-temperature surface 103 of the thermoelectric module 100 or disposed to be brought into contact with the arrangement member 200 disposed on the low-temperature surface 103.

However, the present invention is not limited to the illustrated components of the thermal power generation module 10, and the thermal power generation module 10 may not include the arrangement member 200.

The arrangement member 200 may be configured such that the components of the thermal power generation module 10 are connected to each other. In other words, the arrangement member 200 may be disposed between the components of the thermal power generation module 10 so that the adjacent components may be brought into contact with each other.

For example, the layer of the second arrangement member 202 and 203 disposed between the heat dissipation member 300 and the low-temperature surface 103 of the thermal power generation module 10 may allow the heat dissipation member 300 to be bonded to the thermal power generation module 10.

Further, the arrangement member 200 may impart an adhesive property to a placement surface of the thermal power generation module 10, which is disposed on the high-temperature object, such that the thermal power generation module 10 is disposed on the high-temperature object. For example, the placement surface of the thermal power generation module 10, which is disposed on the high-temperature object, becomes the high-temperature surface 101 of the thermoelectric module 100. Here, the high-temperature surface 101 may be bonded to a surface of the high-temperature object by disposing the first arrangement member 201 on the high-temperature surface 101.

To this end, the arrangement member 200 may be formed of an adhesive material.

The arrangement member 200 may increase the temperature difference ΔT_{TE} between the high-temperature surface 101 and the low-temperature surface 103 to improve heat generation efficiency. This will be described in detail below.

The arrangement member 200 allows the heat between the components to be smoothly moved. To this end, the arrangement member 200 may diffuse the applied heat in a surface direction. Specifically, the arrangement member 200 which is disposed between one component and the other component so that the arrangement member 200 receives heat from the one component may diffuse the heat in the surface direction so that the other component may receive the heat diffused in the surface direction. Accordingly, an area where the other component may receive the heat from the one component is widened by the arrangement member 200, so that the heat may be smoothly transmitted from the one component to the other component. For example, the first arrangement member 201 may be disposed between the high-temperature object and the thermoelectric module 100 to diffuse the heat received from the high-temperature object in the surface direction, thereby transmitting the heat to the thermoelectric module 100. Alternatively, the second arrangement member 202 and 203 may be disposed between the thermoelectric module 100 and the heat dissipation member 300 to diffuse the heat received from the thermoelectric module 100 in the surface direction, thereby transmitting the heat to the heat dissipation member 300.

As a result, since the heat dissipation member 300 is provided, the temperature difference ΔT_{TE} between the two main surfaces of the thermoelectric module 100 may be increased. The heat dissipation member 300 smoothly transmits the heat received from the low-temperature surface 103 to the heat dissipation member 300 and allows the heat to be emitted to the outside air through the heat dissipation member 300, so that the heat on the low-temperature surface 103 may be decreased. Accordingly, the temperature of the low-temperature surface 103 may be reduced. Further, since the heat is smoothly transmitted from the high-temperature object to the high-temperature surface 101 of the thermoelectric module 100, the temperature of the high-temperature surface 101 may be increased. Accordingly, the temperature difference ΔT_{TE} between the high-temperature surface 101 and the low-temperature surface 103 is increased and thus the generation efficiency of the thermoelectric module 100 may be increased.

Hereinafter, the generation efficiency of the thermoelectric module 100 increased by the arrangement member 200 will be described specifically with other examples.

The low-temperature surface 103 of the thermoelectric module 100 may have a region on which the thermoelectric element 130 is disposed and a region on which the support member 140 is disposed. In other words, when observed in a direction perpendicular to the low-temperature surface 103 of the thermoelectric module 100, there may be the region where the support member 140 is disposed and the region where the thermoelectric element 130 is disposed. Specifically, when observed in a direction perpendicular to the low-temperature surface 103 of the thermoelectric module 100, the region on which the thermoelectric element 130 is disposed may be located between regions on which the support members 140 are disposed.

In this case, a temperature of the region on which the support member 140 is disposed and a temperature of the region on which the thermoelectric element 130 is disposed may be different from each other. Specifically, the temperature of the region on which the support member 140 is disposed may be lower than the temperature of the region on which the thermoelectric element 130 is disposed.

Accordingly, the heat is conducted from the region on which the thermoelectric element 130 is disposed to the region on which the support member 140 is disposed, and thus an amount of the heat conducted from the thermoelectric element 130 to the heat dissipation member 300 is reduced.

When the arrangement member 200 is not disposed on the low-temperature surface 103, an amount of heat transmitted from the region on which the support member 140 is disposed to the heat dissipation member 300 may be greater than an amount of the heat transmitted from the region on which the thermoelectric element 130 is disposed to the region on which the support member 140 is disposed. Accordingly, even when the heat is transmitted from the region on which the thermoelectric element 130 is disposed to the region on which the support member 140 is disposed, insufficient heat may not be filled in the region on which the support member 140 is disposed. As a result, heat loss due to the heat transferred from the thermoelectric element 130 to the support member 140 may continue to occur.

However, the heat may be rapidly conducted from the region on which the thermoelectric element 130 is disposed to the region on which the support member 140 is disposed by disposing the arrangement member 200 on the low-temperature surface 103. In other words, the heat accumulated in the thermoelectric element 130 by the arrangement member 200 is conducted to the region on which the support member 140 is disposed, and thus the region on which the thermoelectric element 130 is disposed and the region on which the support member 140 is disposed may rapidly reach a thermal steady state with respect to each other. In other words, the heat loss due to heat transmitted from the region on which the thermoelectric element 130 is disposed to the region on which the support member 140 is disposed may be eliminated in a short time.

As a result, the heat loss from the thermoelectric element 130 to the support member 140 is rapidly reduced by disposing the arrangement member 200, so that heat transmit efficiency from the thermoelectric element 130 to the heat dissipation member 300 may be increased. As a result, the temperature difference ΔT_{TE} between the two main surfaces may be increased so that the generation efficiency may be increased.

Meanwhile, the thermal power generation module 10 may be provided with one arrangement member 200 to which the adhesive property and the thermal diffusivity are imparted, or the thermal power generation module 10 may be provided with a plurality of arrangement members 200 to which the adhesive property and the thermal diffusivity are each imparted. For example, even though the arrangement member 200 to which the adhesive property and the thermal diffusivity are simultaneously imparted may be provided between the thermal power generation module 10 and the heat dissipation member 300, each of the heat dissipation member 300 to which the adhesive property is imparted and the heat dissipation member 300 to which the thermal diffusivity is imparted may also be disposed between the thermal power generation module 10 and the heat dissipation member 300 in a stacked manner.

Meanwhile, the arrangement member 200 may be provided in the form of a film in the thermal power generation module 10 or may be provided in a coated or filled form. For example, the arrangement member 200 may be provided in the form of an adhesive film and disposed in the thermal power generation module 10, or the arrangement member 200 may be provided in the coated or filled form and disposed between the components of the thermal power generation module 10.

The components of the thermal power generation module 10 have been described above.

That is, the thermoelectric module 100 which generates the power according to the thermoelectric operation of the thermal power generation module 10 may be formed with an adhesive surface to be bonded to the high-temperature object, and a certain arrangement member 200 may be disposed to impart the adhesive property to the adhesive surface to be bonded. The thermoelectric element 130 disposed between the two main surfaces of the thermoelectric module 100 may produce the current or power on the basis of the temperature difference ΔT_{TE} formed between the two main surfaces by the heat applied from the high-temperature object. The heat dissipation member 300 may be disposed on the low-temperature surface 103 of the two main surfaces to decrease the temperature of the low-temperature surface 103, and the arrangement member 200, which imparts the adhesive property, may be disposed at a contact area between the heat dissipation member 300 and the low-temperature surface 103 of the thermoelectric module 100 to dispose the heat dissipation member 300 thereon. Also, the thermal diffusivity may be imparted to the arrangement member 200 disposed in the thermal power generation module 10 so that the heat may be smoothly conducted along the components of the thermal power generation module 10.

Hereinafter, an arrangement structure of the thermal power generation module 10 and an insulation rate will be described.

### 3.4 Arrangement of Thermal Power Generation Module and Insulation Rate IR

The thermal power generation module 10 having the above-described components and an arrangement relationship between the components may be disposed on the high-temperature object, and an insulation rate IR may be defined.

Hereinafter, disposition and the insulation rate IR will be described.

### 3.4.1 Disposition of Thermal Power Generation Module

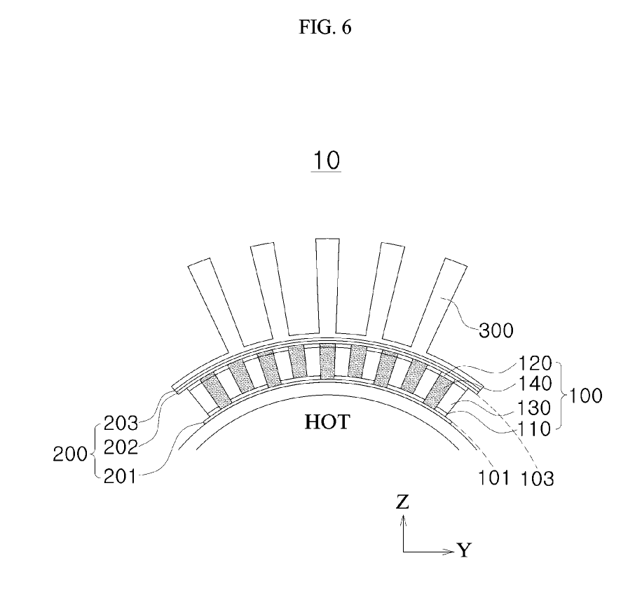

FIG. 6 is a view illustrating the thermal power generation module 10 according to one embodiment, which is disposed on the high-temperature object.

Referring to FIG. 6, when the thermal power generation module 10 is disposed on the high-temperature object, shape of the disposed thermal power generation module 10 may be determined on the basis of an external shape of the high-temperature object.

For example, when the high-temperature object has a curved surface, the thermal power generation module 10 disposed on the curved surface may be bent. Alternatively, the thermal power generation module 10 may be disposed on the curved surface with a curvature.

That is, the thermal power generation module 10 may be bonded without a space separated from the high-temperature object. Accordingly, the generation efficiency of the thermal power generation module 10 may be improved. When the thermal power generation module 10 is disposed on the curved surface of the high-temperature object, if the high-temperature surface 101 of the thermoelectric module 100 is kept flat and disposed on the curved surface, the space may be formed between the high-temperature surface 101 and the curved surface. In this case, the heat emitted from the high-temperature object may not be directly conducted to the thermal power generation module 10 and may be conducted through the separated space. On the other hand, when the high-temperature surface 101 of the thermoelectric module 100 is disposed with the curvature so that the thermoelectric module 100 is disposed without the space separated from the curved surface, the high-temperature surface 101 of the thermoelectric module 100 may receive the heat directly from the high-temperature object. In this case, the high-temperature surface 101 of the thermoelectric module 100 disposed with the curvature has a higher temperature than the high-temperature surface 101 of the thermoelectric module 100 disposed in a flat manner. Accordingly, the temperature difference ΔT_{TE} between the two main surfaces of the thermoelectric module 100 disposed with the curvature increases, and thus the generation efficiency of the thermoelectric module 100 may be improved.

Characteristics, in which the thermal power generation module 10 has the curvature and is disposed on the high-temperature object, may be caused by the flexibility of each component of the thermal power generation module 10. Specifically, each of the thermoelectric module 100, the arrangement member 200, and the heat dissipation member 300 has the flexibility, so that the thermal power generation module 10 may be disposed to be bonded to a front surface of the curved surface of the high-temperature object.

To this end, the arrangement members 200 constituting the thermal power generation module 10 may be formed to a thin thickness to improve the flexibility, and the heat dissipation element 321 and 323 may also be formed of the thin body 310 so as to be bent.

The flexibility of the thermoelectric module 100 may be improved by the support member 140 filling the space between the two main surfaces as described above.

### 3.4.2 Insulation Rate IR

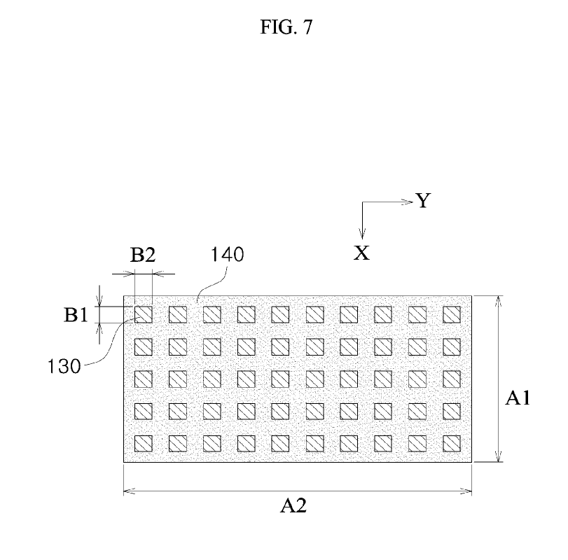

FIG. 7 is a cross-sectional view illustrating the thermoelectric module 100 according to one embodiment.

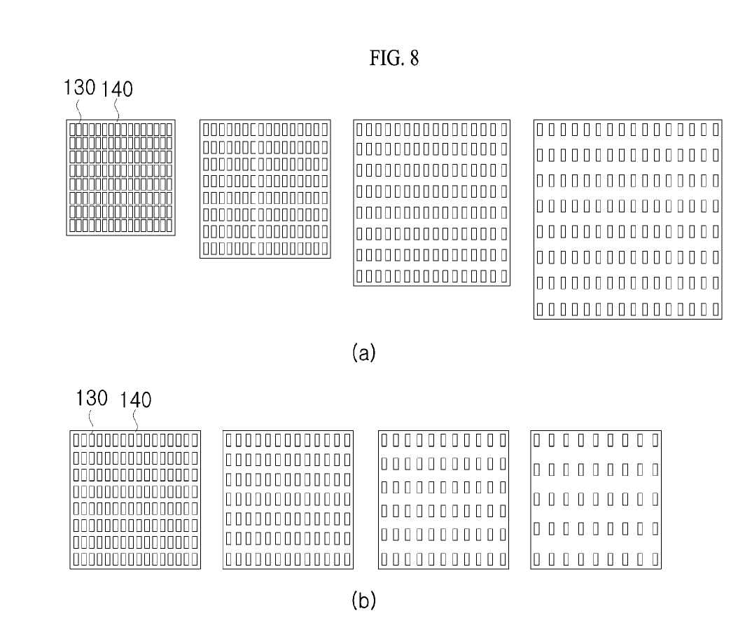

FIG. 8 is a view illustrating an adjustment of the insulation rate IR according to one embodiment.

Referring to FIG. 7, when a cross-section of the thermoelectric module 100 is observed in a direction perpendicular to the main surface, the insulation rate IR of the thermoelectric module 100 may be defined.

The insulation rate IR may be defined as an area occupied by the support member 140 to an area occupied by the thermoelectric element 130 in the cross-section. In other words, the insulation rate IR is a ratio defined in two dimensions when the thermoelectric module 100 is observed in a direction perpendicular to one main surface of the two main surfaces and may be a ratio defined as the area of the support member to the area of the thermoelectric element 130 constituting the thermoelectric module 100 in the two dimensions. In still other words, the insulation rate IR may be defined as the area occupied by the support member to areas occupied by the plurality of thermoelectric elements 130 on the main surface.

The area (hereinafter referred to as a thermoelectric area) occupied by the thermoelectric element 130 constituting the thermoelectric module 100 in the two dimensions may be determined by a width and a height of the thermoelectric element 130, and the area occupied by the support member 140 may be determined by the total area of the thermoelectric module 100 and the thermoelectric area.

Specifically, when the thermoelectric module 100 is observed in a direction perpendicular to the main surface, the width of the thermoelectric module 100 may be A1, the height of the thermoelectric module 100 may be A2, the width of the thermoelectric element 130 may be B1, and the height of the thermoelectric element 130 may be B2. In this case, the thermoelectric area may be B1×B2×n (n is the number of thermoelectric elements 130), and the total area of the thermoelectric module 100 may be A1×A2. An area of the base may be (A1×A2)−(B1×B2×n), that is, the total area minus the area of the thermoelectric element 130.

Accordingly, for example, the insulation rate IR may be calculated as

((A1×A2)/(B1×B2×n))−1.

Meanwhile, the insulation rate IR may be adjusted to maximize the generation efficiency of the thermoelectric module 100.

Referring to FIG. 8, the adjustment of the insulation rate IR may be achieved by adjusting the area of the thermoelectric element 130 and the area of the support member 140 while keeping the area of the main surface constant, or by adjusting the area of the main surface while keeping the area of the thermoelectric element 130 constant.

Referring to FIG. 8(a), the insulation rate IR may be adjusted by maintaining the number of the thermoelectric element 130 constituting the thermoelectric module 100 and the cross-sectional area of the thermoelectric element 130 but widening the two-dimensional area of the thermoelectric module 100. In other words, the insulation rate IR may be adjusted by widening the two-dimensional area of the support member 140 constituting the thermoelectric module 100. The thermoelectric area may be maintained as the two-dimensional area of the thermoelectric module 100 is widened, and the insulation rate IR may be reduced as the area of the support member 140 is increased.

Referring to FIG. 8(b), the insulation rate IR may be adjusted by increasing the number of the thermoelectric element 130 constituting the thermoelectric module 100 while keeping the two-dimensional area of the thermoelectric module 100 the same. The thermoelectric area is increased and the area of the support member 140 is reduced as the number of the thermoelectric element 130 constituting the thermoelectric module 100 is increased, so that the insulation rate IR may be reduced.

The generation efficiency of the thermoelectric module 100 determined according to the adjustment of the insulation rate IR will be described in detail below.

### 4. Operation of Self-Generation Sensor Device

A self-generation sensor device 1 according to one embodiment may perform a self-generation operation and a sensing operation.

The self-generation operation may mean a power generation operation performed in the thermoelectric module on the basis of the temperature difference ΔT_{TE} formed in the self-generation sensor device 1 by the heat applied from the high-temperature object.

The sensing operation may mean an operation of measuring the state of the subject.

Each operation will be described in detail below.

### 4.1. Self-Generation Operation of Self-Generation Sensor Device

A self-generation sensor device 1 according to one embodiment may perform the self-generation operation to produce the power which may be used in the components of the self-generation sensor device 1. The power may be used as the driving power of each component.

The thermal power generation operation may be performed by disposing the thermal power generation module 10 on the high-temperature object.

The thermal power generation operation i) may be performed on the basis of the temperature difference ΔT_{TE} between the two main surfaces of the thermoelectric module 100, and ii) the power according to the thermal power generation operation may be produced by a thermoelectric operation of the thermoelectric module 100. An amount of the power produced by the thermoelectric operation of the thermoelectric module 100 may be proportional to the temperature difference ΔT_{TE} and may be proportional to an area S_{TE} of the thermoelectric element 130. That is, the generation efficiency may be proportional to the temperature difference ΔT_{TE} between the two main surfaces and the area S_{TE} of the thermoelectric element 130

The generation efficiency may be defined as an amount of power produced per hour according to the thermal power generation operation.

The temperature difference ΔT_{TE} and the area S_{TE} of the thermoelectric element 130 may be inversely proportional to each other. In other words, the temperature difference ΔT_{TE} may be increased when the area S_{TE} of the thermoelectric element 130 is reduced, and the temperature difference ΔT_{TE} may be reduced when the area S_{TE} of the thermoelectric element 130 is increased.

Accordingly, the generation efficiency according to the thermal power generation operation may be maximally improved according to an optimal temperature difference ΔT_{TE} and an optimal area S_{TE} of the thermoelectric element 130, and for this, the insulation rate IR which allows the temperature difference ΔT_{TE} and the area S_{TE} of the thermoelectric element 130 to be optimal may be determined.

Hereinafter, the thermal power generation operation will be described in detail.

### 4.1.1 Thermal Conduction and Power Generation of Thermoelectric Element

As described above, thermal power generation operation according to one embodiment may be mainly performed by the thermoelectric element 130 on the basis of the temperature difference ΔT_{TE} according to the thermal conduction.

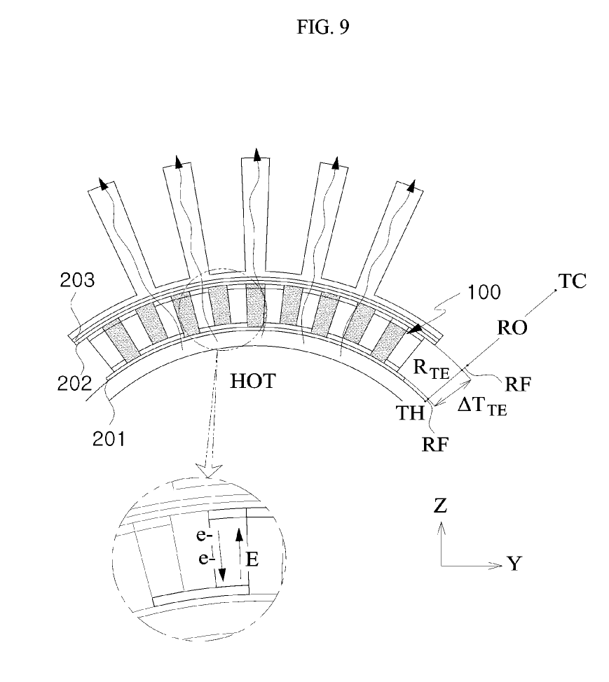

FIG. 9 is a view illustrating a thermal conduction path through the thermal power generation module 10 and thermal resistance of each component of the thermal power generation module 10 according to one embodiment.

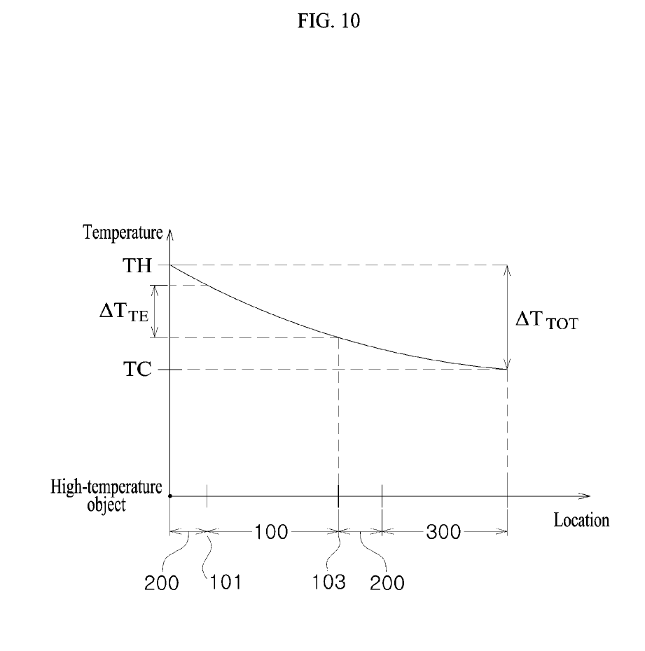

FIG. 10 is a graph illustrating the temperature gradient of the thermal power generation module 10 according to one embodiment.

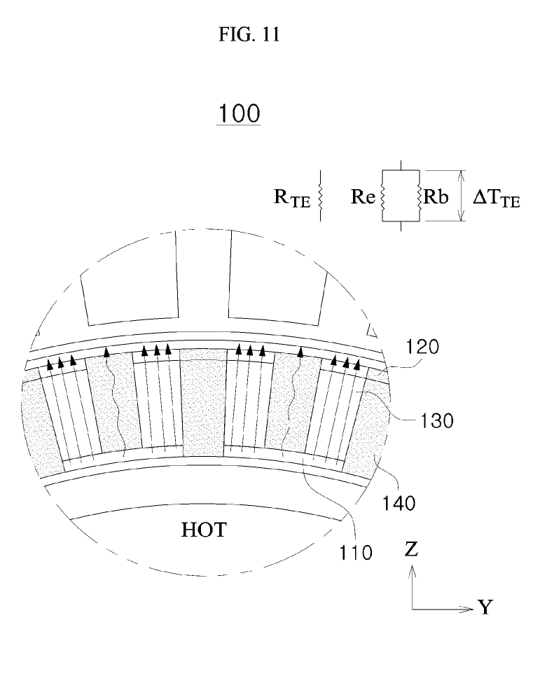

FIG. 11 is a view illustrating thermal conduction through the thermoelectric module and thermal resistance of the thermoelectric module according to one embodiment.

Hereinafter, description will be made with reference to FIGS. 9 to 11.

Thermal power generation operation of the thermoelectric module 100 according to one embodiment may be determined on the basis of the temperature difference ΔT_{TE} between the high-temperature surface 101 and the low-temperature surface 103 of the thermoelectric module 100 and the area S_{TE} of the thermoelectric element 130.

Hereinafter, the temperature difference ΔT_{TE} between the high-temperature surface 101 and the low-temperature surface 103, which are determined according to the thermal conduction, will be described first.

Referring to FIGS. 9 and 10, the temperature difference ΔT_{TE} between the high-temperature surface 101 and the low-temperature surface 103 may be determined on the basis of the thermal conduction and the thermal resistance of each component of the thermal power generation module 10.

Referring to FIG. 9, the heat conducted through the thermal power generation module 10 may be conducted along a certain path. The heat emitted from the high-temperature object may be applied to a first arrangement member 201 disposed on the high-temperature object, the heat may be transmitted from the first arrangement member 201 to the thermoelectric module 100, the heat may be transmitted from the thermoelectric module 100 to a second arrangement members 202 and 203, and the heat may be transmitted from the second arrangement members 202 and 203 to the heat dissipation member 300.

As illustrated in FIG. 10, the temperature gradient of the thermal power generation module 10 may be determined by the heat conducted through the thermal power generation module 10. In other words, the temperature may be determined for each region and for each component of the thermal power generation module 10 by the heat conducted through the components of the thermal power generation module 10.

The heat is emitted from the heat dissipation member 300, and when the amount of the heat applied from the high-temperature object is equal to the amount of the heat emitted from the heat dissipation member 300, the thermal power generation module 10 is in a thermal steady state.

Referring to FIG. 10, the temperature difference may be formed on the entire thermal power generation module 10 disposed on the high-temperature object in the thermal steady state. When the thermal power generation module 10 is disposed on the high-temperature object, the thermal steady state may mean a time interval in which the temperature of the thermal power generation module 10 is not suddenly changed after a certain time. When the amount of the heat applied from the high-temperature object to the thermal power generation module 10 and the amount of the heat emitted from the heat dissipation member 300 of the thermal power generation module 10 to the outside air become equal to each other, the thermal power generation module 10 may enter the thermal steady state.

Hereinafter, the temperature difference formed on the entire thermal power generation module 10 may be defined as a total temperature difference ΔT_{TOT}. The total temperature difference ΔT_{TOT} may be caused by the temperature gradient formed by continuously emitting the heat from the high-temperature object to the outside air through the heat dissipation element 321 and 323 passing through the components of the thermal power generation module 10 in the steady state. The total temperature difference ΔT_{TOT} may mean the temperature difference ΔT_{TE} between the first arrangement member 201 of the thermal power generation module 10, which is disposed closest to the high-temperature object, and an outer surface of the heat dissipation member 300 of the thermal power generation module 10, which is farthest from the high-temperature object. The temperature of the first arrangement member 201 may be formed at a high temperature TH close to the temperature of the high-temperature object, and the temperature of the region of the heat dissipation member 300, which is the farthest from the high-temperature object, may be formed at a low temperature TC. Thus, the temperature difference ΔT_{TE} may be a difference between the high temperature TH and the low temperature TC.

In addition, the temperature difference ΔT_{TE} may be formed between the high-temperature surface 101 and the low-temperature surface 103 of the thermoelectric module 100 as the temperature difference ΔT_{TOT} is formed on the entire thermal power generation module 10. The temperature difference ΔT_{TE} between the high-temperature surface 101 and the low-temperature surface 103 may be the temperature difference ΔT_{TE} between the high-temperature surface 101 and the low-temperature surface 103 of the thermal power generation module 10 in the thermal steady state. The temperature difference ΔT_{TE} between the high-temperature surface 101 and the low-temperature surface 103 may be defined as a thermoelectric temperature difference ΔT_{TE}. That is, when the amount of the heat applied to the high-temperature surface 101 and the amount of the heat conducted in a direction of the heat dissipation member 300 through the low-temperature surface 103 become equal to each other, the two main surfaces of the thermoelectric module 100 may enter the thermal steady state. The temperature difference ΔT_{TE} may be formed between the two main surfaces in the steady state.

Meanwhile, in the thermal steady state, the temperature of the components of the thermal power generation module 10 is no longer changed. In other words, the temperature gradient formed in the thermal power generation module 10 is maintained constant after a certain period of time (after the steady state) since the thermal power generation module 10 is disposed on the high-temperature object. Meanwhile, the temperature gradient formed in the thermal power generation module 10 may be suddenly changed in a section of the thermoelectric module 100. Referring to FIG. 10, the degree of the temperature changed in the section of the thermoelectric module 100 may be greater than on other sections. In other words, an absolute value of a slope of the temperature change in the section of the thermoelectric module 100 may be greater than in the other sections. This may be due to the support member 140 constituting the thermoelectric module 100. The heat is accumulated on the high-temperature surface 101 as the heat is blocked by the support member 140 so that the temperature difference ΔT_{TE} between the high-temperature surface 101 and the low-temperature surface 103 may be rapidly increased.

The temperature difference ΔT_{TE} between the two main surfaces may be determined on the basis of the thermal resistance of the components.

The thermal power generation module 10 has a total thermal resistance (RF+RTE+RO), and the total thermal resistance may be determined on the basis of a thermal resistance RF of the arrangement members 200, the thermal resistance RTE of the thermoelectric module 100 and a thermal resistance RO of the heat dissipation member 300 constituting the thermal power generation module 10. Since the above-described components are thermally in series relationship, the total thermal resistance may be calculated as a sum of the thermal resistances of the components.

The first arrangement member 201 and the second arrangement member 200 have thermal resistances, and the thermoelectric module 100 may have the thermoelectric thermal resistance RTE, and the heat dissipation member 300 has the heat dissipation thermal resistance.

The temperature difference between the components may be determined by the total temperature difference ΔT_{TOT}×((thermal resistance of each component)/(total thermal resistance (RF+RTE+RO))). In other words, the total temperature difference ΔT_{TOT} may be distributed to each component according to the thermal resistance of each component. That is, when the total thermal resistance (RF+RTE+RO) is constant, the temperature difference between the components may be formed in proportion to the thermal resistance of each component.

That is, the temperature difference ΔT_{TE} between the two main surfaces is proportional to the thermal resistance RTE of the thermoelectric module 100, and thus in order for the temperature difference ΔT_{TE} to be concentrated and distributed between the two main surfaces, the thermal resistance RTE of the thermoelectric module 100 should be increased. In other words, the thermal resistance RTE of the thermoelectric module 100 should be increased to increase the generation efficiency of the thermal power generation operation.

Referring to FIG. 11, the increase in the thermal resistance RTE of the thermoelectric module 100 may be achieved by the support member 140 filled in the space between the two main surfaces. In other words, the thermal resistance RTE of the thermoelectric module 100 may be increased by filling the support member 140, which is provided as a thermal insulating material, in the space between the two main surfaces.

The thermal resistance RTE of the thermoelectric module 100 may be determined on the basis of a thermal resistance Re of the thermoelectric element 130 and a thermal resistance Rb of the support member 140.

The thermal resistance of the thermoelectric element 130 itself may be increased as the area S_{TE} of the thermoelectric element 130 decreases due to the filling of the support member 140. The increased thermal resistance of the thermoelectric element 130 may be caused by the relational expression: R=p^{1/A} (where p is the thermal resistivity, A is the area, and 1 is a thickness).

The support member 140 may be provided as an insulating material, and the thermal resistance of the support member 140 may be greater than the thermal resistance of the thermoelectric element 130.

As a result, the thermal resistance RTE of the thermoelectric module 100 may be increased by filling the support member 140 therein. Referring again to FIG. 11, it may be seen that the heat conducted through the thermoelectric module 100 is mainly conducted through the thermoelectric element 130 by filling the support member 140 therein. That is, the path through which the heat is conducted through the thermoelectric module 100 is reduced by filling the support member 140, thereby increasing the thermal resistance RTE of the thermoelectric module 100.

As a result, the thermoelectric module 100 may perform the thermoelectric operation on the basis of the temperature difference ΔT_{TE} between the two main surfaces. Electrons are moved in the N-type semiconductor on the basis of the temperature difference ΔT_{TE} between the two main surfaces, and the current may flow in the direction opposite to the direction of an electron movement. Specifically, when the thermoelectric module 100 is disposed on the high-temperature object, the electrons move on the basis of the temperature difference between the high-temperature surface 101 and the low-temperature surface 103 to make the current flow, and the movement direction of the electrons is determined in a direction toward the low-temperature surface 103. On the contrary, in the P-type semiconductor, the electrons move in the direction toward the high-temperature surface 101.

The current formed in the thermoelectric element 130 moves along the conductor member, and the current flows to the entire thermoelectric module 100.

The current formed in the entire thermoelectric module 100 may be converted to the power.

Hereinafter, the generation efficiency determined on the basis of the area S_{TE} of the thermoelectric element 130 will be described.

When the area S_{TE} of the thermoelectric element 130 is increased, the generation efficiency may be enhanced.

The enhancement of the generation efficiency may be caused by the fact that the amount of the power produced from the thermoelectric module 100 is proportional to an allowable current amount of the thermoelectric element 130. The allowable current amount may be defined as a limit of the amount of the current which may flow in the thermoelectric element 130.

Specifically, as the area S_{TE} of the thermoelectric element 130 is widened, the amount of the current that may flow through the thermoelectric element 130 may be increased. When the area S_{TE} of the thermoelectric element 130 is narrow, correspondingly, the number of electrons, which may move in the thermoelectric element 130, may be reduced. Accordingly, even when a great temperature difference ΔT_{TE} is formed between the two main surfaces, the amount of current, which is flowing, is limited by the number of the electrons. On the other hand, when the area S_{TE} of the thermoelectric element 130 is wide, correspondingly, the number of electrons, which may move in the thermoelectric element 130, may be increased. Accordingly, when the temperature difference ΔT_{TE} is formed between the two main surfaces, the amount of current, which may flow through the thermoelectric element 130, may be greater than that of the thermoelectric element 130 having a narrow area. That is, in the case of the thermoelectric element 130 having the wide area, a great amount of the current may flow, so that the amount of the power to be produced is increased. As a result, the wider the area of the thermoelectric element 130, the higher the generation efficiency.

Alternatively, the enhanced generation efficiency may be caused by an increase in a power generation area of the thermoelectric element 130. The power generation area may be defined as an area where the power may be generated in the thermoelectric element 130. Specifically, the power generation area may be a region where the current is generated in the thermoelectric element 130 so that the power may be generated by the current. As the area of the thermoelectric element 130 is increased, the power generation area is increased, and as a result, the amount of the power which is generated by the temperature difference between the two main surfaces in the thermoelectric element 130 may be increased. Accordingly, as the area S_{TE} of the thermoelectric element 130 increases, the generation efficiency may be enhanced.

### 4.1.2 Optimal Insulation Rate IR

Hereinafter, an optimal insulation rate IR for maximizing the generation efficiency will be described.

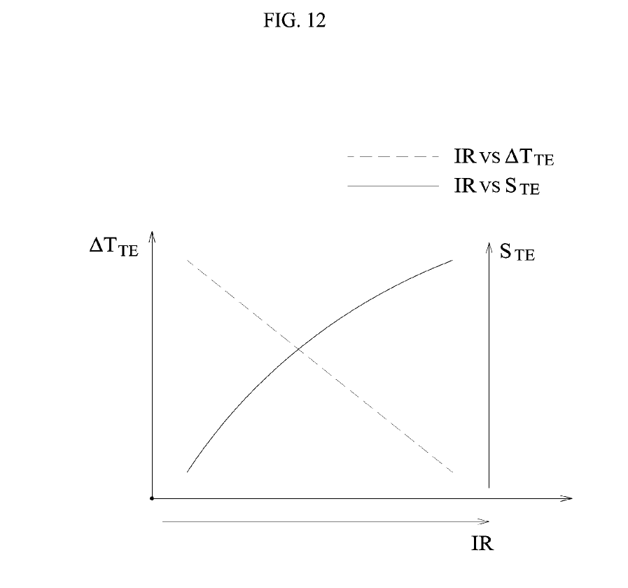

FIG. 12 is a graph showing a relationship between the insulation rate IR, the thermoelectric temperature difference ΔT_{TE}, and the thermoelectric area according to one embodiment.

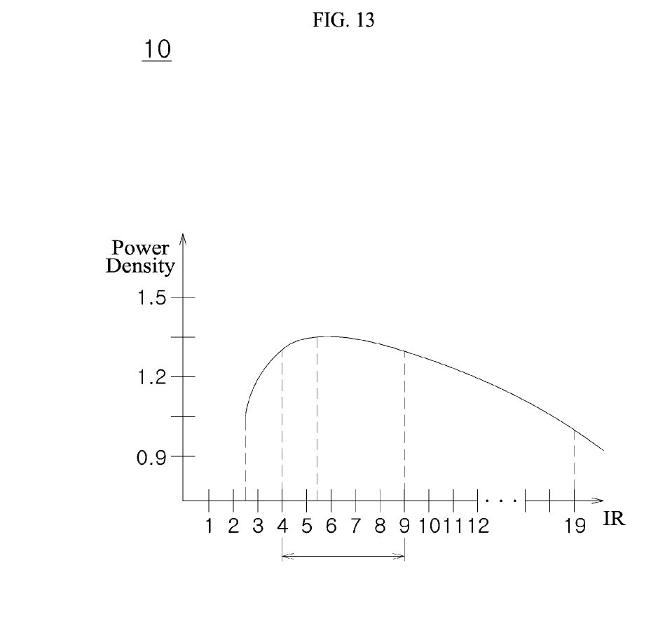

FIG. 13 is a graph illustrating the amount of the power according to the insulation rate IR according to one embodiment.

Hereinafter, description will be made with reference to FIGS. 12 and 13.

As described above, the amount of the power produced by the thermal power generation operation and the generation efficiency are proportional to the temperature difference ΔT_{TE} between the two main surfaces and the area S_{TE} of the thermoelectric element 130.

However, since the temperature difference ΔT_{TE} between the two main surfaces and the area S_{TE} of the thermoelectric element 130 have a relationship inversely proportional to each other, in order to achieve the highest generation efficiency according to the thermoelectric operation, an optimal thermoelectric temperature difference ΔT_{TE} and an optimal thermoelectric area S_{TE} should be determined. The optimum may be defined as a value of one element for achieving the highest generation efficiency.

Meanwhile, when the thermoelectric area S_{TE} is increased, the reduced thermoelectric temperature difference ΔT_{TE} may be caused by a decrease in the thermal resistance RTE of the thermoelectric module 100 due to a decrease in the area of the support member 140 constituting the thermoelectric module 100.

The highest generation efficiency may be determined according to the insulation rate IR. In other words, the optimal thermoelectric temperature difference ΔT_{TE} and the optimal thermoelectric area S_{TE} may be achieved by adjusting the insulation rate IR.

Hereinafter, the optimal insulation rate IR will be described.

Referring to FIG. 12, a thermoelectric temperature difference ΔT_{TE} according to one embodiment may be proportional to the insulation rate IR and the area S_{TE} of the thermoelectric element 130 may be inversely proportional to the insulation rate IR.

The temperature difference ΔT_{TE} between the two main surfaces may be proportional to the insulation rate IR. In other words, the temperature difference ΔT_{TE} may be concentrated in the thermoelectric module 100 in proportion to the insulation rate IR.

Increasing the insulation rate IR may mean that the thermal resistance RTE of the thermoelectric module 100 is increased. The area of the support member 140 filling the space between the two main surfaces of the thermoelectric module 100 is widened as the insulation rate IR is increased so that the thermal resistance RTE of the thermoelectric module 100 may be increased.

As a result, since the thermal resistance RTE of the thermoelectric module 100 is proportional to the insulation rate IR, the thermoelectric temperature difference ΔT_{TE} may be proportional to the insulation rate IR.

The area of the thermoelectric element 130 may be inversely proportional to the insulation rate IR.

The area of the support member 140 filling the space between the two main surfaces of the thermoelectric module 100 is widened as the insulation rate IR is increased so that the area of the thermoelectric element 130 constituting the thermoelectric module 100 may be narrowed. That is, the area of the thermoelectric element 130 may be inversely proportional to the insulation rate IR.

Accordingly, the optimal insulation rate IR which determines the optimal temperature difference ΔT_{TE} between the two main surfaces and the optimal area of the thermoelectric element 130 may be determined. In other words, when the insulation rate IR is increased, the temperature difference ΔT_{TE} between the two main surfaces is concentrated, but the area of the thermoelectric element 130 is reduced, and when the insulation rate IR is decreased, the area of the thermoelectric element 130 is increased, but the temperature difference ΔT_{TE} between the two main surfaces is reduced, so that the insulation rate IR that optimizes those previously mentioned may be determined.

FIG. 13 may be a graph showing the amount of the power measured by adjusting the insulation rate IR by adjusting the area of the thermoelectric element 130 and the area of the support member 140 while keeping the area of the main surface constant. Alternatively, FIG. 13 may be the graph showing the amount of the power measured by adjusting the insulation rate IR by adjusting the area of the main surface while keeping the area of the thermoelectric element 130 constant.

Referring to FIG. 13, the range of the optimal insulation rate IR may be in a range of 4 to 9. Particularly, the range of the optimal insulation rate IR to achieve the highest power generation rate may be in a range of 5 to 5.5. Alternatively, in the main surface, a ratio of the area of the thermoelectric element 130 to the area of the support member may be 1 or more and 5 or less. Particularly, the ratio of the area of the thermoelectric element 130 to the area of the support member to achieve the highest power generation rate may be in a range of 4.5 to 5.

When the insulation rate IR is 4 or less, since the temperature difference between the two main surfaces for the power generation is not sufficiently formed, the generation efficiency of the thermoelectric module 100 may be reduced. As illustrated in FIG. 13, it may be seen that a power density of the thermoelectric module 100 is reduced in a section of the insulation ratio IR of 4 or less.

When the insulation rate IR is 9 or more, since the area of the thermoelectric element 130 disposed between the two main surfaces is reduced, the amount of current to be used in the production of the power may not be sufficiently formed in the thermoelectric element 130. This may be caused by the allowable current amount of the thermoelectric element 130, which is reduced due to the reduced area of the thermoelectric element 130. As a result, when the insulation rate IR is 9 or more, the area of the thermoelectric element 130 is reduced, so that the generation efficiency may be reduced. As illustrated in FIG. 13, the power density of the thermoelectric module 100 is decreased in a section in which the insulation rate IR is 9 or more. When the area of the thermoelectric element 130 relative to the area of the support member is 1 or less, the generation efficiency may be reduced. This may be caused by the reduced power generation area of the thermoelectric element 130. When the area of the thermoelectric element 130 relative to the area of the support member is 1 or less, the power generation area for producing the power is greatly reduced, which may cause a reduction in the area of the thermoelectric element 130 participating in the power generation.

Accordingly, the insulation rate IR for achieving the highest generation efficiency may be in a range of 4 to 9. In other words, the insulation rate IR for determining the optimal thermoelectric temperature difference ΔT_{TE} and the optimal thermoelectric area may be determined to be 4 to 9.

### 4.2 Sensing Operation of Self-Generation Sensor Device

A thermal power generation module 10 according to one embodiment may generate the data related to the state of a subject by performing the sensing operation and deliver the state data related to the state of the subject to other external components.

The state data generated by the thermal power generation module 10 may be generated by the operation of the sensor unit 30 but may also be generated on the basis of electrical characteristics of the current or power generated in the thermoelectric module 100. Since the state data related to the state of the subject, which is generated by the operation of the sensor unit 30, is a well-known technique, a repetitive description thereof will be omitted.

Hereinafter, the sensing operation performed on the basis of the current or power produced by the thermoelectric module 100 will be described in detail.

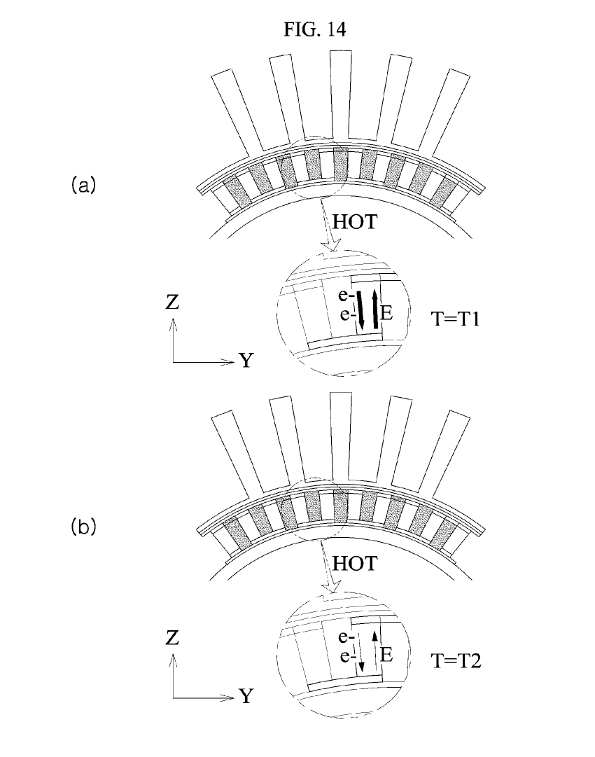

FIG. 14 is a view illustrating the current generated in the thermoelectric module according to one embodiment.

Referring to FIG. 14, a state data related to the state of the subject may be generated on the basis of the data related to the electrical characteristics of the current formed in the thermoelectric module 100. The state data may be data related to a temperature state of the subject. The data related to the electrical characteristics of the current may include an amount of the current, an amount of power on the basis of the amount of the current, a current density, and the like.

The amount of the current formed in the thermoelectric module 100 or the amount of the power on the basis of the current may be based on the amount of the heat applied to the thermoelectric module 100. In other words, the amount of the current and the amount of the power may be determined according to the temperature of the high-temperature object and the amount of the heat emitted from the high-temperature object on the basis of the temperature of the high-temperature object. Accordingly, the self-generation sensor device 1 may detect the temperature of the high-temperature object using the thermoelectric module 100 due to the fact that the amount of the current and the amount of the power may be reversely calculated to detect the temperature of the high-temperature object. In this case, the subject to be sensed by the thermoelectric module 100 and the high-temperature object which is an object on which the thermoelectric module 100 is disposed may be considered to be the same.

The self-generation sensor device 1 may detect the temperature of the high-temperature object on the basis of the state data. In other words, the self-generation sensor device 1 may separately generate temperature data related to the temperature of the high-temperature object on the basis of the state data. To this end, a certain lookup table may be implemented in the controller 40 for the sensing operation using the thermoelectric module 100. The lookup table may be defined as a comparison table including information on the temperature data corresponding to the data related to the current. On the basis of the lookup table, the controller 40 may convert the state data generated on the basis of the current of the thermoelectric module 100 to the temperature data. In this case, the temperature data is delivered to the server 2 or the personal terminal 3, thus allowing the user to receive the status of the temperature state of the subject.

Alternatively, it is possible to simply deliver the state data to the server 2 or the personal terminal 3 to allow the server 2 or personal terminal 3 to convert the state data to the data related to the temperature of the subject and supply the data to the user.

Meanwhile, when the data related to the current is converted to the data related to the temperature of the subject, the conversion may be performed by reflecting the insulation rate IR. Depending on the insulation rate IR, the amount of the current or power generated in the thermoelectric module 100 may be changed even at the same temperature of the high-temperature object. Accordingly, the data related to the current may be converted to the data related to the temperature by using the lookup table in which the insulation rate IR is reflected. For example, a first current in a case, in which the insulation rate IR is in a range of 4 to 9, may be converted to a first temperature, and a second current in a case, in which the insulation rate IR is 4 or less, may be converted to the first temperature. In order to reflect the insulation rate, the insulation rate may be measured in advance and preset or may be automatically measured by the self-generation sensor device 1. In the case of automatically measuring the insulation rate IR, it may be performed by applying a predetermined current to the thermoelectric module 100 and obtaining an output value fed back therefrom.

Referring to FIGS. 14(a) and 14(b), the self-generation sensor device 1 may generate state data streaming on the basis of the data related to the current formed with time. The state data streaming may be data related to the temperature of the high-temperature object, which is changed with time. The amount of the current and the amount of the power on the basis of the amount of the current formed in the thermoelectric module 100 may be changed according to the temperature of the subject by time points. The streaming data may be generated on the basis of the changed amount of the current and the changed amount of the power.

When a temperature T of the subject at a first-time point is a first temperature T1, the heat corresponding to the first temperature may be emitted from the subject. Due to the emitted heat, a first temperature difference ΔT_{TE} may be formed in the thermoelectric module 100 of the thermal power generation module 10. Accordingly, the electrons are moved in the thermoelectric module 100 on the basis of the first temperature difference ΔT_{TE}, and thus a first current, which is the current equivalent to the moving electrons, may be formed. On the basis of the first current, a first amount of power may be generated in the self-generation sensor device 1.

When the temperature T of the subject at a second-time point is a second temperature T2, the heat corresponding to the second temperature may be emitted from the subject. Due to the emitted heat, a second temperature difference ΔT_{TE} may be formed in the thermoelectric module 100 of the thermal power generation module 10. Accordingly, the electrons are moved in the thermoelectric module 100 on the basis of the second temperature difference ΔT_{TE}, and thus a second current, which is the current equivalent to the moving electrons, may be formed. On the basis of the second current, the first amount of power may be generated in the self-generation sensor device 1.

As a result, the amount of the current produced by the time points by the thermoelectric module 100 may be measured, which may be generated as the state data streaming.

The state data streaming may be used to detect the defects of the subject. Specifically, it is possible to detect a specific time point in the state data streaming so that the defects of the subject are detected. The specific time point may be defined as a time point at which the amount of the current or power is suddenly changed. For example, the streaming data may accumulate only the data related to the first current on the basis of the first temperature of the high-temperature object, and then suddenly accumulate the data related to the second current on the basis of the second temperature of the high-temperature object at the specific time point. The self-generation sensor device 1 may detect the presence or absence of the defect in the subject on the basis of the sudden change in the data related to the current. Whether or not the defect is detected may be reported to the user, so that the user may easily grasp whether or not there is a defect in the device on which the self-generation sensor device 1 is disposed in the facility.

Meanwhile, the detection of such a defect may be performed in the self-generation sensor device 1, but may also be performed in the server 2 or the personal terminal 3 to which the state data streaming is transmitted.

### 4.3 Self-Generation Operation and Sensing Operation of Self-Generation Sensor Device

A self-generation sensor device 1 according to one embodiment may perform at least one of the self-generation operation and the sensing operation, or both.

Hereinafter, a case in which the self-generation sensor device 1 performs both the self-generation operation and the sensing operation will be described.

The self-generation operation and the sensing operation may be performed at the same time or at different times.

When the self-generation operation and the sensing operation are performed at the same time, the production of the power according to the self-generation operation and the generation of the subject data according to the sensing operation may be performed at the same time.

In other words, when not only the self-generation operation but also the sensing operation is performed by the thermal power generation module 10, the thermal power generation module 10 may produce the power so that the power may be used in other components and the subject data may be simultaneously generated on the basis of the power.

When the self-generation operation and the sensing operation are performed at different times, the power production time interval for producing the power and the subject data generation time interval for generating the subject data may exist separately.

The self-generation sensor device 1 may produce only the power in the power production time interval and generate only the subject data related to the subject in the subject data generation interval.

In other words, when not only the self-generation operation but also the sensing operation is performed by the thermal power generation module 10, the thermal power generation module 10 may only produce the power during one-time interval and generate the subject data on the basis of the power during another one-time interval.

### 5. Operation Method of Self-Generation Sensor Device

Hereinafter, an operation method of the self-generation sensor device 1 will be described.

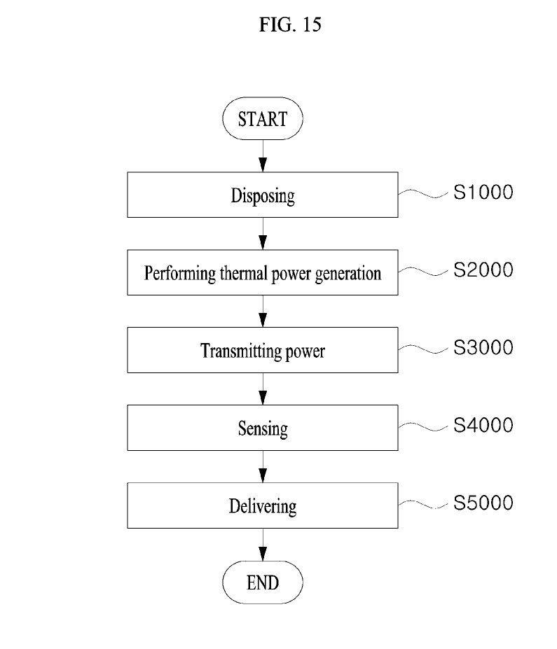

FIG. 15 is a flowchart of a sensing method of the self-generation sensor device 1 according to one embodiment.

Referring to FIG. 15, the operation method according to one embodiment may include disposing operation S1000, thermal power generation operation S2000, power transmission operation S3000, sensing operation S4000, and delivering operation S5000. In the embodiments, operations S1000 to S5000 may be performed simultaneously, but any one of the operations may be performed at an earlier time. Operations S1000 to S4000 may all be performed, but all of operations S1000 to S5000 are not always performed and only at least one of operations S1000 to S5000 may be performed.

Each operation will be described below.

The disposing operation S1000 may be an operation of disposing the thermal power generation module 10 on the high-temperature object. The thermal power generation module 10 may be disposed so that the thermoelectric module 100 of the thermal power generation module 10 is connected to the high-temperature object.

The thermal power generation operation S2000 may be an operation in which the thermal power generation module 10 generates the power for driving the components of the thermal power generation module 10.

The power transmission operation S3000 may be an operation of transmitting the power generated by the thermal power generation module 10 to the components. In this operation, the power may be transmitted to at least one of the power storage module, the communication unit, the sensor unit, and the controller of the thermal power generation module 10.

The sensing operation S4000 may be an operation of sensing the states of the various apparatus in the facility by the thermal power generation module 10. The sensing may be performed by the sensor unit included in the thermal power generation module 10 or performed on the basis of the amount of current/power generated in the thermal power generation module 10.

The delivering operation S5000 may be an operation of delivering the data related to the subject, which is generated by the thermal power generation module 10, to the server or the personal terminals.

Hereinafter, a specific example of the sensing method of the self-generation sensor device 1 will be described.

### 5.1 Disposing on Heat Pipe

A self-generation sensor device 1 according to one embodiment may be disposed on the heat pipe to perform the operation.

In the disposing operation S1000, the self-generation sensor device 1 may be disposed on the heat pipe in the factory facility. The high-temperature surface of the thermal power generation module 10 of the self-generation sensor device 1 may be disposed to come into contact with the heat pipe. Since the heat pipe has a curved surface, the thermal power generation module 10 may be disposed to come into contact with the heat pipe in a shape corresponding to the curved surface of the heat pipe. In other words, the thermal power generation module 10 is brought into close contact with the heat pipe without a separate space.

In the thermal power generation operation S2000, heat emitted from high-temperature steam or gas flowing through the heat pipe may be conducted to the thermal power generation module 10. The temperature difference may be formed between the high-temperature surface and the low-temperature surface of the thermal power generation module 10 on the basis of the conducted heat. The thermal power generation module 10 may perform the self-generation operation on the basis of the temperature difference.

In the power transmission operation S3000, the thermal power generation module 10 may transmit the generated power to the components.

In the sensing operation S4000, the self-generation sensor device 1 may perform the sensing operation on the basis of the generated power. Here, an object of the subject may be the heat pipe or a steam trap connected to the heat pipe. The data related to the state of the heat pipe or steam trap is obtained to diagnose whether the state of the subject is faulty or not.

The delivering operation S5000 may be an operation of delivering the data related to the subject, which is generated by the thermal power generation module, to the server or the personal terminals.

### 5.2 Disposing on Human Body

A self-generation sensor device 1 according to one embodiment may be disposed on a human body to perform the self-generation operation and the sensing operation.

In the disposing operation S1000, the self-generation sensor device 1 may be disposed on one surface of the human body. The high-temperature surface of the thermal power generation module 10 of the self-generation sensor device 1 may be disposed to come into contact with the human body. The surface of the human body usually has a curved surface, and the shape of the curved surface may be partially deformed depending on a pressure applied to the surface of the human body. The thermal power generation module 10 has flexibility and thus may be brought into close contact with the irregularly shaped surface of the human body. In other words, the thermal power generation module is brought into close contact with the surface of the human body without a separated space.

In the thermal power generation operation S2000, heat according to a body temperature formed in the human body may be conducted to the thermal power generation module 10. The temperature difference may be formed between the high-temperature surface and the low-temperature surface of the thermal power generation module 10 on the basis of the conducted heat. The thermal power generation module 10 may perform the self-generation operation on the basis of the temperature difference.

In the power transmission operation S3000, the thermal power generation module 10 may transmit the generated power to the components.

In the sensing operation S4000, the self-generation sensor device 1 may perform the sensing operation on the basis of the generated power. Here, an object of the subject may be a part of the human body on which the thermal power generation module 10 is disposed or an environment around the human body. When the object of the subject is a part of the human body, the self-generation sensor device 1 may detect a change in temperature of the human body to detect whether the human body is diseased or not. Also, when the object of the subject is the environment around the human body, the self-generation sensor device 1 may sense the state of the environment around the human body on which the self-generation sensor device 1 is disposed.

The delivering operation S5000 may be an operation of delivering the data related to the subject, which is generated by the thermal power generation module 10, to the server or the personal terminals.

In the above-described self-generation sensor device and the self-generation sensor system including the same, the operations constituting each embodiment are not essential, and therefore, each embodiment may selectively include the above-described operations. Also, each operation constituting each embodiment is not necessarily performed according to the order described, and the operation described later may be performed before the operation described earlier. Further, it is also possible that one operation is repeatedly performed while each operation is being conducted.

1. A self-generation sensor device which is installed on a high-temperature object and uses power produced by performing self-generation as driving power, the self-generation sensor device comprising:
a sensor unit;
a communication unit configured to transmit data reflecting a sensed value of the sensor unit; and
a thermal power generation module including a pair of main surfaces including a high-temperature surface thermally connected to the high-temperature object and a low-temperature surface which is a surface opposite to the high-temperature surface, a thermoelectric module including a plurality of thermoelectric elements disposed between the pair of main surfaces and producing the power by using a temperature difference between the both main surfaces due to the high-temperature object and a support member filled in a space between the both main surfaces to support the thermoelectric elements, and a heat dissipation member connected to the low-temperature surface,
wherein the support member is provided as an insulating material that concentrates the temperature difference between the both main surfaces among heat transmission paths from the high-temperature object to outside air through the thermal power generation module.

2. The self-generation sensor device of claim 1, wherein a ratio of an area occupied by the support member to an area occupied by the plurality of thermoelectric elements on the main surface is 5 or more so that generation efficiency of each of the plurality of thermoelectric elements increases as the temperature difference is concentrated between the both main surfaces.

3. The self-generation sensor device of claim 2, wherein the area occupied by the plurality of thermoelectric elements to the area occupied by the support member on the main surfaces is at least 10% or more so that a generation area of the thermoelectric elements for performing power generation by the temperature difference applied between the both main surfaces becomes sufficient.

4. The self-generation sensor device of claim 3, wherein the support member includes bubbles so that the temperature difference is further concentrated between the both main surfaces.

5. The self-generation sensor device of claim 4, wherein an arrangement member configured to diffuse heat in a surface direction is disposed between the thermoelectric module and the heat dissipation member so that the heat of the low-temperature surface is decreased and thus the temperature difference is further concentrated between the both main surfaces.

6. The self-generation sensor device of claim 4, wherein a contact surface coming into contact with the high-temperature object is formed on the high-temperature surface, and an adhesive property is imparted to the contact surface.

7. The self-generation sensor device of claim 6, wherein, when the thermoelectric module is disposed on a curved surface of the high-temperature object, the thermoelectric module having a curvature corresponding to the curved surface is disposed on the curved surface so that there is no separated space between the curved surface and the low-temperature surface.

8. The self-generation sensor device of claim 1,
wherein a temperature gradient is formed between the low-temperature surface of the thermal power generation module and an end of the heat dissipation member in a steady state in which an amount of the heat transmitted from the high-temperature object to the thermoelectric module is identical to an amount of the heat emitted from the heat dissipation member to the outside air, and
wherein the temperature gradient is suddenly changed in the thermoelectric module due to a reduction in a movement of the heat conducted through the thermoelectric module by the support member.

9. The self-generation sensor device of claim 8, wherein a ratio of an area occupied by the support member to an area occupied by the plurality of thermoelectric elements on the main surfaces is 5 or more so that the temperature gradient in the thermoelectric module is suddenly changed.

10. The self-generation sensor device of claim 9, wherein the ratio of the area occupied by the support member to the area occupied by the plurality of thermoelectric elements on the main surfaces is 9 or less so that an allowable amount of current of the thermoelectric elements for performing power generation by the temperature gradient becomes sufficient.

11. The self-generation sensor device of claim 6, wherein the thermoelectric elements are surrounded by the support member.

12. The self-generation sensor device of claim 11,
wherein the thermal power generation module includes a plurality of conductor members configured to electrically connect the plurality of adjacent thermoelectric elements, and
wherein the support member is disposed between the plurality of conductor members so that an electrical connection between the plurality of conductor members, which are to be adjacent to each other due to a disposition of the thermal power generation module on a curved surface, is prevented when the thermal power generation module is disposed on the curved surface.

13. The self-generation sensor device of claim 12, wherein the plurality of conductor members and the support member are disposed on the contact surface, and the plurality of conductor members and the thermoelectric elements are supported by the support member.

14. A self-generation sensor device which is installed in a subject and detects temperature information on the subject on the basis of power produced by performing self-generation, the self-generation sensor device comprising:
a thermal power generation module including a pair of main surfaces including a high-temperature surface thermally connected to the subject and a low-temperature surface which is a surface opposite to the high-temperature surface, a thermoelectric module including a plurality of thermoelectric elements disposed between the pair of main surfaces and producing the power by using a temperature difference between the both main surfaces due to the subject, and a support member filled in a space between the both main surfaces to support the thermoelectric elements, and a heat dissipation member connected to the low-temperature surface; and
a controller configured to generate state data related to a temperature state of the subject based on electrical characteristics of the power produced by the thermoelectric module.
